(19) United States
(12) Patent Application Publication
(10) Pub. No.: US 2024/0178696 A1
(43) Pub. Date: May 30, 2024

(54) SYSTEMS AND METHODS FOR CONTROLLED BATTERY HEATING

(71) Applicant: Lontra Inc, Centennial, CO (US)

(72) Inventors: Daniel A. Konopka, Aurora, CO (US); John Richard HOWLETT, III, Centennial, CO (US); William E. CHECK, Denver, CO (US); Chris MORRONI, Denver, CO (US); Davit KESSNER, Denver, CO (US); Zhong WANG, Sugar Land, TX (US); Ryan WU, Denver, CO (US)

(21) Appl. No.: 18/433,354

(22) Filed: Feb. 5, 2024

Related U.S. Application Data
(63) Continuation-in-part of application No. 18/113,578, filed on Feb. 23, 2023.
Application No. 18/113,578 is a continuation-in-part of application No. 17/699,016, filed on Mar. 18, 2022.
(60) Provisional application No. 63/443,327, filed on Feb. 3, 2023.
(60) Provisional application No. 63/313,147, filed on Feb. 23, 2022.
(60) Provisional application No. 63/331,633, filed on Apr. 15, 2022.
(60) Provisional application No. 63/163,011, filed on Mar. 18, 2021.
(60) Provisional application No. 63/313,147, filed on Feb. 23, 2022.

(51) Int. Cl. H02J 7/06; H01M 10/615; H01M 10/637; H02J 7/00; G01R 31/389

(52) U.S. Cl. CPC H02J 7/06; H01M 10/615; H01M 10/637; H02J 7/0048; H02J 7/0063; H02J 7/0068; G01R 31/389; H02J 7/00711; H02J 7/00712; H02J 7/007194

(57) ABSTRACT

Systems and methods for heating a battery, which may be performed alone or in combination with charging or discharging a battery. In some implementations, heating involves applying an alternating current waveform, which may be sinusoidal, to a battery. In some implementations, the heating signal is applied at a frequency and/or current with little or no net charge to the battery.

### CROSS-REFERENCE TO RELATED APPLICATIONS

This application is related to and claims priority under 35 U.S.C. § 119(e) from U.S. Provisional Patent Application No. 63/443,327 filed Feb. 3, 2023, titled “Heating Wave,” the entire contents of which are incorporated herein by reference for all purposes.

This application is also related to and claims priority as a continuation-in-part of U.S. Nonprovisional patent application Ser. No. 18/113,578 filed Feb. 23, 2023, titled “Systems and Methods for Controlled Battery Heating,” which claims priority under 35 U.S.C. § 119(e) from U.S. Provisional Patent Application No. 63/313,147 filed Feb. 23, 2022, titled “Systems and Methods for Controlled Battery Heating Sourcing Current To and From the Battery,” and from U.S. Provisional Patent Application No. 63/331,633 filed Apr. 15, 2022, titled “Systems and Methods for Controlled Battery Heating,” and is a continuation-in-part of U.S. patent application Ser. No. 17/699,016 filed Mar. 18, 2022, titled “System and Methods of Controlled Battery Heating Sourcing Current To and From The Battery and Discharge Signal Conditioning From the Same,” which claims benefit of priority under 35 U.S.C. § 119(e) from U.S. Provisional Patent Application No. 63/163,011 filed Mar. 18, 2021, titled “Powering A Load from a Battery Discharging with Harmonic Components,” and from U.S. Provisional Patent Application No. 63/313,147 filed Feb. 23, 2022, titled “Systems and Methods for Controlled Battery Heating Sourcing Current To and From the Battery,” all of which are hereby incorporated by reference in their entirety.

### TECHNICAL FIELD

Embodiments of the present invention generally relate to systems and methods for heating and/or charging or discharging a battery.

### BACKGROUND AND INTRODUCTION

Countless different types of electrically powered devices, such as power tools, mobile computing and communication devices, portable electronic devices, and electrically powered vehicles of all sorts including scooters and bicycles, use rechargeable batteries as a source of operating power. Rechargeable batteries are limited by finite battery capacity and must be recharged upon depletion. Recharging a battery may be inconvenient as the powered device must often be stationary during the time required for recharging the battery. Depending on battery size, recharging can take hours. Moreover, battery charging is often accompanied by degradation of battery performance. As such, significant effort has been put into developing battery charging technology to reduce the time needed to recharge the battery, improve battery performance, reduce degradation of the battery from charging, among other things.

Various battery types including lithium-based batteries often cannot be charged at low temperatures without damaging the cell. In some cases, particularly in liquid electrolyte batteries, the electrolyte may freeze. Attempting to charge when the electrolyte is frozen or otherwise when the battery temperature is below certain thresholds, can damage the battery through electrode plating. This can obviously be a concern in many use cases where a battery is discharged but is at a temperature that is too low for conventional charging to take place.

It is with these observations in mind, among others, that various aspects of the present disclosure were conceived.

### SUMMARY

One aspect of the present disclosure involves a system for heating a battery comprising a processor in communication with a circuit where the processor is configured to execute instructions to heat a battery by controlling the circuit to alternate between sourcing current to the battery and sinking current from the battery, and the combination of sourcing current to the battery and sinking current from the battery heats the battery.

Another aspect of the present disclosure involves a battery powered system comprising a battery and a processor in operable communication with a charging circuit of the battery, the processor operably coupled to the charging circuit to control at least one harmonic component of a discharge signal from the battery. The system further may include a signal conditioning element positioned between the battery and a load system, the signal conditioning element receiving the discharge signal from the battery and providing a DC signal to the load system.

Another aspect of the present disclosure involves a method of charging a battery comprising, responsive to obtaining information indicative of whether the battery may be charged, alternating between sourcing current to the battery and sinking current from the battery to heat the battery. The method may further comprise receiving a temperature measurement of the battery providing the information indicative of whether the battery may be charged. In one possible example, obtaining a response from the battery based on application of a signal with a known harmonic provides the information indicative of whether the battery may be charged. In another possible example, the response is an impedance response, and the information is a battery temperature correlation to the impedance response. In various embodiments, an impedance or admittance response is discussed, and it should be recognized that the term impedance response encompasses its inverse an admittance response and the term admittance or admittance response similarly encompasses its inverse impedance or impedance response.

Another aspect of the present disclosure involves a method of charging a battery comprising, responsive to obtaining information indicative of whether the battery may accept charge, applying a harmonically tuned signal to the battery, where the harmonically tuned signal is composed of at least one harmonic associated with a conductance response and a reactance response to heat the battery. The method may further involve receiving a temperature measurement of the battery providing the information indicative of whether the battery may be charged. Another example may involve obtaining a response from the battery based on application of a signal with a known harmonic providing the information indicative of whether the battery may be charged. In one example, the response is an impedance response, and the information is a battery temperature correlation to the impedance response. The at least one harmonic may be a higher frequency than a kinetic and a diffusive process of the battery. If the signal is composed of multiple harmonics, then the collection of harmonics may be higher frequencies than the kinetic and diffusive processes of the battery.

Another aspect of the present disclosure involves a method of heating a battery comprising generating a repeating signal to apply to a battery, the repeating signal comprising a first portion and a second portion over a period, the first portion defining a sinusoidally shaped leading edge rising to a body portion terminating at a falling edge, the first portion defining a first percentage of the period, the second portion comprising an alternating current following the falling edge of the first portion, the second portion defining a second percentage of the period where the first percentage and the second percentage comprise the period.

Another aspect of the present disclosure involves a method of charging a battery comprising applying a probe signal to a battery, the probe signal comprising a plurality of harmonics including at least a first harmonic and a second harmonic. The system/method further involves obtaining a voltage response and a current response at the battery based on the probe signal, and based on the voltage response and the current response, generating an impedance spectrum including at least a first impedance of the first harmonic and a second impedance of the second harmonic, the first impedance being less than the second impedance, and generating a charge signal to apply to the battery, the charge signal including a sinusoidally shaped leading edge of the frequency of the first harmonic.

Another aspect of the present disclosure involves a method of heating a battery comprising applying an alternating current to a battery to heat a battery where the alternating current is at a frequency greater than a frequency at an inflection point in a conductance response or less than a frequency at an inflection point in a susceptance response. More particularly, the frequency is greater than a frequency at an inflection point in a conductance response and less than a frequency at an inflection point in a susceptance response.

Yet another aspect of the present disclosure involves a method of heating a battery comprising applying an alternating current to a battery to heat the battery, the alternating current at a frequency where a conductance response of the battery is decreasing and a susceptance response of the battery is increasing.

Further aspects of the present disclosure involve a method of heating a battery comprising generating a repeating signal to apply to a battery, the repeating signal having first portion and a second portion over a period, the first portion defining a leading edge rising to a body portion terminating in a falling edge, the second portion comprising an alternating current following the falling edge of the first portion, and wherein a frequency of the alternating current is selected to be between 2 kHz and 1 MHz.

The alternating current may be a sinusoidal shape, an approximation of the sinusoidal shape, a linear piecewise approximation of the sinusoidal shape. The alternating current may also be composed of more than one harmonic, be composed of a harmonic and some distribution of harmonics centered on the harmonic, or other shapes. In the specific case of a linear piecewise approximation of a sinusoidal shape, each period of the linear piecewise approximation comprises at least three linear segments having different slopes.

In some examples, the method may further include selecting an offset for the alternating current based on a state of charge of the battery. For example, when the state of charge is at or near 0% SOC, the offset may be selected to charge the battery, e.g., at a charge current (positive) offset at or less than C/20 for the battery type. In contrast, when the state of charge is at or near 100% SOC, the offset may be selected to discharge the battery, e.g., at a discharge current (negative) offset at or less than C/10 for the battery type.

In various examples, the frequency is selected such that at least one full period of the alternating current fits between the falling edge of the first portion of a first repeating signal and the leading edge of the first portion of a second repeating signal. Further, the alternating current may be selected such that a number of alternating current periods completed between sequential first portions of the signal is a whole number. In various embodiments, the frequency of the alternating current is selected to target a net zero coulomb exchange.

In some embodiments, a battery or pack may be characterized and the frequency of the alternating current selected from a table or the like, which may also take into account SOC and temperature. In another embodiment, the method may further involve probing the battery to dynamically determine an upper frequency bound and a lower frequency bound with the lower frequency bound at an inflection point in a conductance response and the upper frequency bound at an inflection point in a susceptance response. The frequency may be selected to fall between the upper frequency bound and the lower frequency bound.

In another aspect, a method of heating a battery comprises generating a repeating signal to apply to a battery, the repeating signal having first portion and a second portion over a period, the first portion defining a charging portion terminating in a falling edge, the second portion comprising an alternating current following the falling edge of the first portion, and wherein a frequency of the alternating current is based on at least one of a conductance response or a susceptance response.

The frequency may be between an upper frequency bound and a lower frequency bound with the lower frequency bound at an inflection point in the conductance response and the upper frequency bound at an inflection point in the susceptance response.

In some arrangements, the method further involves probing the battery to dynamically determine the upper frequency bound and the lower frequency bound with the lower frequency bound at an inflection point in the conductance response and the upper frequency bound at an inflection point in the susceptance response.

In various embodiments, the frequency is further based on a temperature of the battery.

These and other features of the present disclosure are discussed in greater detail below.

### BRIEF DESCRIPTION OF THE DRAWINGS

The various objects, features, and advantages of the present disclosure set forth herein will be apparent from the following description of embodiments of those inventive concepts, as illustrated in the accompanying drawings. It should be noted that the drawings are not necessarily to scale or include every detail and may be representative of various features of an embodiment, the emphasis being placed on illustrating the principles and other aspects of the inventive concepts. Also, in the drawings the like reference characters may refer to the same parts or similar throughout the different views. It is intended that the embodiments and figures disclosed herein are to be considered illustrative rather than limiting.

FIG. 1 is a circuit diagram of a battery heating and charging system in accordance with one embodiment, the diagram further illustrating a charging path and a load path from a power supply.

FIG. 2 is a circuit diagram of the battery heating and charging system of FIG. 1, the diagram further illustrating a discharge path from the battery in conjunction with a load path from a power rail including a power supply.

FIG. 3 is a circuit diagram of the battery heating and charging system of FIGS. 1 and 2, the diagram further illustrating a charging path and a load path from the power rail (e.g., a capacitor thereon) with the power supply not sourcing energy (e.g., current).

FIG. 4 is a signal diagram of a first example heating signal comprising a symmetrically shaped charge current portion and discharge current portion, in accordance with one embodiment.

FIG. 5 is a signal diagram of a second example of a heating signal comprising an asymmetrically shaped charge current portion and discharge current portion, in accordance with one embodiment.

FIG. 6 is a signal diagram of a third example of a heating signal comprising differently shaped charge current portions and discharge current portions, in accordance with one embodiment.

FIG. 7 is an example of a profile that heats the battery until the battery temperature will allow charging.

FIG. 8 is a flow chart of a method of heating a battery, in accordance with one embodiment.

FIG. 9A is a signal diagram of a first combined charging and heating signal, in accordance with one embodiment.

FIG. 9B is a signal diagram of a second combined charging and heating signal, in accordance with one embodiment.

FIG. 10A is a signal diagram of a charging signal including a 0 A rest period, in accordance with one embodiment.

FIG. 10B is a signal diagram of a charging signal including a rest period with a non-zero current, in accordance with one embodiment.

FIG. 11 is a flow chat of a method of shaping a charge signal in accordance with one embodiment.

FIG. 12 is a flow chart of a method of identifying a charge current level accounting for battery temperature, in accordance with one embodiment.

FIG. 13 is a system diagram including a signal conditioning element to covert an unconventional non-DC current from a battery to a signal for consumption by power conversion or otherwise a load that conventionally requires a DC signal.

FIG. 14A is a conductance response diagram for a Lithium-Ion battery, the conductance response used to establish a frequency for a heating signal, in one embodiment.

FIG. 14B is a susceptance response diagram for a Lithium-Ion battery, the susceptance response used to establish a frequency for a heating signal, in one embodiment.

FIG. 15A is a peak susceptance and peak conductance plot for a 2.5 Ah battery cell at 50% SOC, the peaks identified at temperatures from −20 to 40 degrees Celsius.

FIG. 15B is a peak susceptance and peak conductance plot for a 3.0 Ah battery cell at 50% SOC, the peaks identified at temperatures from −20 to 40 degrees Celsius.

FIG. 15C is a peak susceptance and peak conductance plot for a 4.0 Ah battery cell at 50% SOC, the peaks identified at temperatures from −20 to 40 degrees Celsius.

FIG. 16 is an example of a combined charging and heating waveform, in one embodiment.

FIG. 17A is an ICA discharge plot of a first 5.0 Ah battery cell illustrating three curves taken at the start of test, two weeks into the test, and four weeks into the test, the three curves substantially overlap and hence appear as a single curve in the depicted graph, the test done in a temperature controlled chamber while applying a continuous heating signal.

FIG. 17B is an ICA charge plot of the first 5.0 Ah battery cell illustrating three curves taken at the start of test, two weeks into the test, and four weeks into the test, the three curves substantially overlap and hence appear as a single curve in the depicted graph, the test done in a temperature controlled chamber while applying a continuous heating signal.

FIG. 17C is an ICA discharge plot of a second 5.0 Ah battery cell illustrating three curves taken at the start of test, two weeks into the test, and four weeks into the test, the three curves substantially overlap and hence appear as a single curve in the depicted graph, the test done in a temperature controlled chamber while applying a continuous heating signal.

FIG. 17D is an ICA charge plot of the second 5.0 Ah battery cell illustrating three curves taken at the start of test, two weeks into the test, and four weeks into the test, the three curves substantially overlap and hence appear as a single curve in the depicted graph, the test done in a temperature controlled chamber while applying a continuous heating signal.

FIG. 17E is an ICA discharge plot of a third 5.0 Ah battery cell illustrating three curves taken at the start of test, two weeks into the test, and four weeks into the test, the three curves substantially overlap and hence appear as a single curve in the depicted graph, the test done in a temperature controlled chamber while applying a continuous heating signal.

FIG. 17F is an ICA charge plot of the third first 5.0 Ah battery cell illustrating three curves taken at the start of test, two weeks into the test, and four weeks into the test, the three curves substantially overlap and hence appear as a single curve in the depicted graph, the test done in a temperature-controlled chamber while applying a continuous heating signal.

FIG. 18 is a diagram illustrating an example of a computing system which may be used in implementing embodiments of the present disclosure.

### DETAILED DESCRIPTION

Systems, circuits, and methods are disclosed herein for heating and charging (recharging) a battery. The terms charging and recharging are used synonymously herein. Aspects of the present disclosure may provide several advantages, alone or in combination, relative to conventional charging. For example, the charging techniques described herein may allow for heating a battery to sufficient level for charging to take place. In some cases, the battery temperature is monitored, and when below a threshold, the system initiates a heating sequence before charging, and transitions to a charging sequence when the battery is sufficiently warmed. The temperature thresholds may be tailored to various battery chemistries. In one example, temperature thresholds for heating, combinations of heating and charging, and charging may depend on or be related to a freezing temperature of a liquid electrolyte, although various possible temperature parameters and thresholds are contemplated. Moreover, some battery chemistries such as those in solid-state batteries do not have a liquid electrolyte but are nonetheless affected by temperature such that charging at too low a temperature may damage the battery. The system may also involve circuit elements that allow for charging techniques that reduce the rate at which an anode is damaged, can control heat generated by the battery either by generating heat or minimizing heat generation above certain levels when charging has commenced, which may have several follow-on effects such as reducing electrode and other battery damage, reducing fire or short circuit risks, and the like.

When discharging a battery whether for heating or to power a load, aspects of the present disclosure further involve a discharge signal conditioning element positioned between the battery and the load or integrated within the load. Conventionally, batteries are discharged to a load with a DC signal or convert a DC signal from the battery to an AC signal such as with an inverter or the like to power an AC motor. However, aspects of the present disclosure involve, whether heating or otherwise, an unconventional non-DC discharge signal. The discharge signal conditioning element serves to condition the unconventional discharge signal suitable for the load or element powering the load using the energy from the battery.

In one example, the various embodiments discussed herein manage energy into and out of a battery by generating a charge or discharge signal that is controllably shaped. The shapes may be tuned based on impedance effects of the battery to various harmonics. In some instances, during heating, the shape, which may include harmonic aspects, in charge or discharge, is tailored to heat the battery and minimize damage to the battery or to achieve other effects. In some instances, during charging, the shape or content of the charge signal, which may also include harmonic aspects, is optimized for charge. During heating, the system may select harmonic attributes associated with relatively higher impedance as compared to charging where the system may control the charge signal to include harmonic attributes associated with relatively lower impedance.

The system may further use a model of one or more components of a charge/discharge signal shaping circuit. Conventional charge techniques like constant current or constant voltage (DC techniques) do not involve charge signal shaping and hence control is relatively straightforward, and there is no need for the charge and discharge signal shaping techniques discussed herein. The model may be used to confirm and/or adjust the controls for generating the signal to or from the battery, and likely a combination during heating. In some instances, aspects of the shape and/or content of the charge signal may correspond to a harmonic (or harmonics) associated with an optimal transfer of energy to the battery, although the purpose of the system is to be able to efficiently generate any arbitrarily shaped charging signal and apply the same to the battery, among other goals. In other instances, particularly around battery heating, which may occur prior to charging, involves shaping and/or defining a signal intended to cause heating and minimize or eliminate charging during the time when the battery is being heated to prepare it for charge (or discharge). The shape or signal content, which may be any arbitrary shape defined by the controls and, in some instances includes defined harmonic content, is nonetheless controlled.

In one possible implementation, a feed-forward technique of utilizing a model to determine the control signals for defining a charge/discharge signal may provide several advantages including accuracy and speed of signal adjustment. Moreover, the arrangement may be operable with fewer components than other approaches thereby reducing costs and using less printed circuit board real estate, among other advantages. The approach further, whether using the model or not, may include adjustment of the signal from one of heating to charging when an appropriate temperature of the battery is reached, followed by signal adjustments as the battery is charged.

Aspects of the system, whether using a model or not, may further include feedback of temperature and other battery parameters both during the heating phase as well as transitioning to and through the charging phase. Feedback, alone or in conjunction with a model, may allow the system to adjust for component drift, adjust for effects of temperature or other effects on circuit components, adjust for changes in the battery, and periodically provide additional data to the system and/or the model to alter its output, among other things. Moreover, the system may use battery temperature to select between heating or charging, and to, in some instances, transition between a heating phase to a phase where charging is optimized without heating, which may include a transition phase of both heating and charging.

The term “battery” in the art and herein can be used in various ways and may refer to an individual cell having an anode and cathode separated by an electrolyte, solid or liquid, as well as a collection of such cells connected in various arrangements. A battery or battery cell is a form of electrochemical device. Batteries generally comprise repeating units of sources of a countercharge and electrode layers separated by an ionically conductive barrier, often a liquid or polymer membrane saturated with an electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different types of batteries ranging from an individual cell to batteries involving different possible interconnections of cells such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead-acid batteries, various types of nickel batteries, and solid-state batteries, to name a few. The various implementations discussed herein may also apply to different structural battery arrangements such as button or “coin” type batteries, cylindrical cells, pouch cells, and prismatic cells.

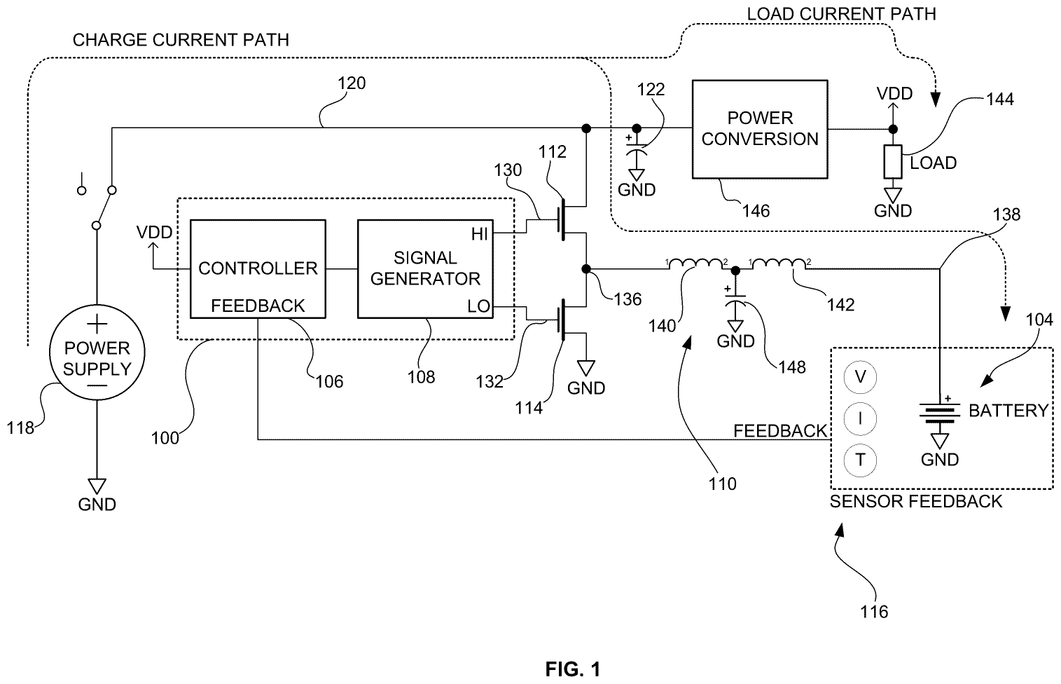

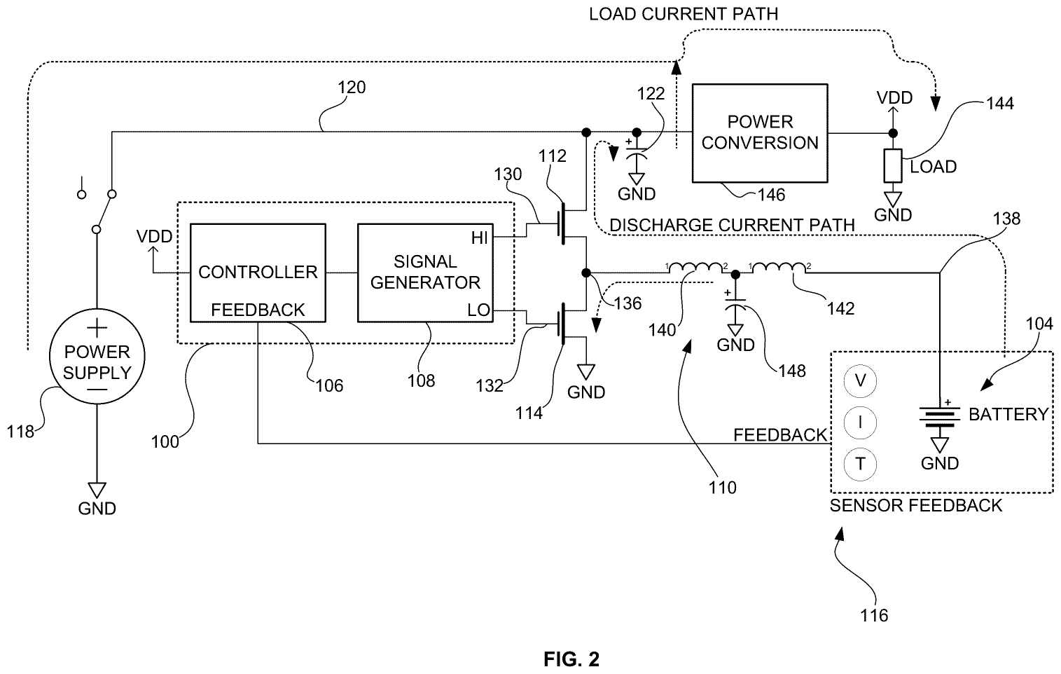

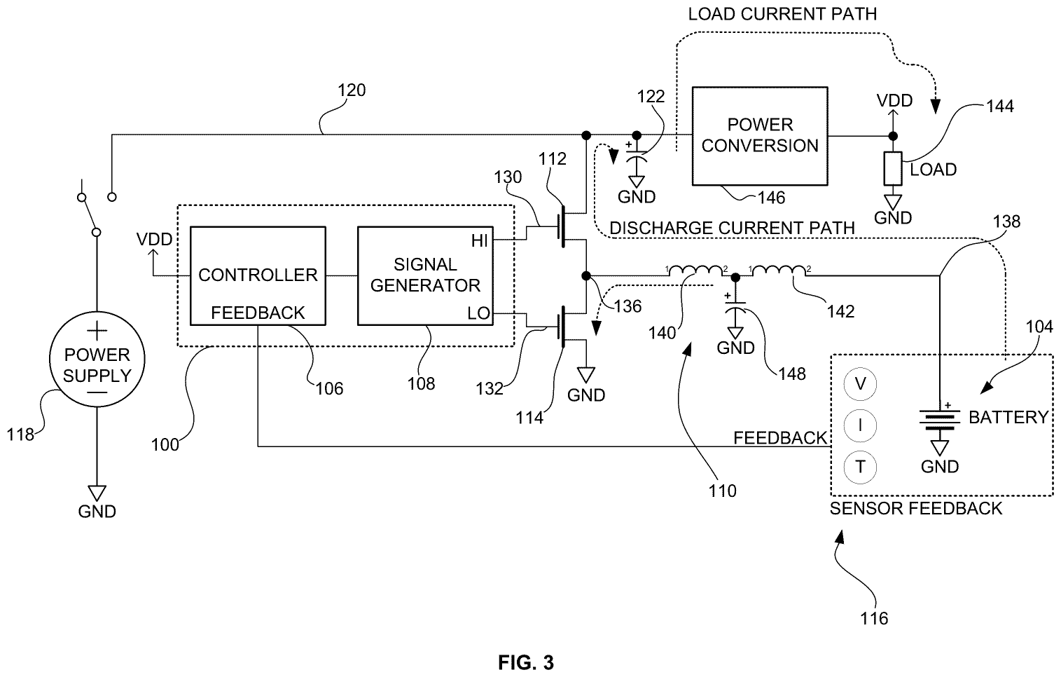

FIGS. 1 through 3 illustrate a battery heating and charging circuit topology in accordance with one embodiment of the present disclosure. Arrows illustrated in the figures define current flow paths during different operational states of the system. In FIG. 1, the system is shown in a configuration sourcing current (charging) to the battery and powering a load. In FIG. 2, the system is shown in a configuration drawing current from the battery (discharging or sinking), a discharge path to a capacitor on the rail and powering a load with the power supply on (connected to the rail). In FIG. 3, the system is shown in a configuration drawing current from the battery to a capacitor on the rail along with powering a load with the power supply off (not connected to the rail). In both FIGS. 2 and 3, there is also an arrow showing the “blip” path to the lower, second transistor, which blipping initiates the discharge current path.

FIG. 1, as well as FIGS. 2 and 3, are schematic diagrams illustrating an example charge signal generator arrangement 100 for heating, charging and/or discharging a battery 104. The generator includes a processing unit or more generally a control unit 106 that may include a controller, such as a microcontroller, FPGA (field-programmable gate array), ASIC (application-specific integrated circuit), microprocessor, combinations thereof, or other processing arrangement, which may be in communication with a signal generator 108 that produces controls for generating a charge signal from a charge signal shaping circuit 110. The controller may be in communication with a model, which may be part of the generator, to produce the control instructions to the charge signal shaping circuit. The control unit, including the controller and a model if present, may be an integrated unit. The system may also receive feedback including battery measurements from a battery measurement unit 116, such as current and/or voltage measurements at battery terminals of the battery 104 in the presence of a signal (heat, charge and/or discharge), and those battery measurements may be used to obtain impedance measurements and/or affect heating or charge control. In general, the generator may also include or be operably coupled with a power source 118, which may be a voltage source or a current source. In one embodiment, the power source 118 is a direct current (DC) current or voltage source, although alternating current (AC) sources are also contemplated. In various alternatives, the power source 118 may include a DC source providing a unidirectional current, an AC source providing a bidirectional current, or a power source providing a ripple current (such as an AC signal with a DC bias to cause the current to be unidirectional. In general, the power source 118 supplies the charge energy, e.g., current, that may be shaped or otherwise defined by the control unit 106 and circuit 110 to produce a controllably shaped charge signal to heat, charge and/or discharge the battery 104. In one example, a controller 106 may provide one or more inputs to the signal generator 108, which controls switches to generate pulses to the circuit 110, which may also be referred to as a filter, which produces the shaped signal at the battery.

In some instances, the signal shaping circuit 110 may alter energy from the power source 118 to generate a signal that is shaped based on conditions at the battery 104, such as a signal that at least partially corresponds to a harmonic or harmonics based on the impedance when a signal comprising the harmonic or attributes of the harmonic is applied to the battery 104. In the example of FIG. 1 and otherwise, the circuit 100 may include the battery measurement unit 116 connected to the battery 104 to measure cell voltage and/or charge current, as well as other battery attributes like temperature and measure, calculate or otherwise obtain the impedance the battery 104 based on the same. In one example, battery characteristics may be measured based on the signal to or from the battery. In another example, battery cell characteristics may be measured as part of a routine that applies a signal with varying frequency attributes to generate a range of battery cell characteristic values associated with the different frequency attributes to characterize the battery, which may be done prior to heating, charging or discharging, during charging, periodically during the same, and may be used in combination with look-up techniques, and other techniques. The battery characteristics may vary based on many physical of chemical features of the battery, including a state of charge and/or a temperature of the battery. As such, the battery measurement circuit 116 may be controlled by the controller 106 to determine various battery characteristic values of the battery 104 during heating, recharging of the battery, and/or powering a load among other times, and provide the measured battery characteristic values to the controller 106 or other parts of the generator 100.

During charge, the controller 106 may generate an intended charge signal for efficient charging of the battery 104. For example, a determined impedance of the battery 104 or signal definitions characterized from understanding impedance effects of signals on a battery may be used by the controller 106 to generate or select a charge signal with attributes that correspond to a harmonic associated with an optimal impedance, which may be a range of impedances, for energy transfer, which optimal impedance may be associated with a minimum impedance value of the battery 104. As such, the controller 106 may execute a charge signal algorithm that outputs a charge signal shape based on measured, characterized and/or estimated charging conditions of the battery 104. Generally speaking, the signal generator controls the switches to generate a sequence of pulses at node 136, which are converted by circuit 110 to the charge signal shape. Similarly, during heating, the battery may be characterized, based on temperature, to understand impedance effects of a charge or discharge signal on the battery and a signal controlled based on the same. Here, the node 136 may similarly be controlled but such that current with defined impedance attributes is both sourced to and sunk from the battery by way of the circuit 110. It should be recognized that heating may also involve transitioning from current into and out of the battery, characterized in a way, that optimizes heating, minimizes or eliminates plating, and minimizes any energy storage in the battery during the heating sequence. The signal generator 108 may generate one or more control signals based on the heat or charge signal algorithm and provide those control signals to the signal shaping unit 110. The control signals may, among other functions, shape or otherwise define the signal to and from the battery to approximate the shaped charge signal determined, selected or otherwise obtained by the controller 106. The charge signal shaping circuit 110 may further filter any unwanted frequency attributes from the signal. In some instances, the shaped charge signal may be any arbitrarily shaped signal, such that the signal whether heating, charging or discharging, is not a constant DC signal and does not conform to a conventional repeating charge signal, such as a repeating square wave or triangle wave charge signal.

The circuits of FIGS. 1-3 include switching elements 112, 114, which may be considered part of circuit 110, to generate an initial sequence of controlled pulses at node 136, which are then converted into a shaped signal by filter 110, to produce a signal that is applied to or from the battery, in accordance with one embodiment. The switching elements may also be used to generate a discharge signal from the battery by similarly generated pulses at node 136, without the presence of charge current on the rail 120.

As introduced, the circuit 100 may include one or more components to shape a signal that intentionally causes battery heating through a coordinated combination of charge and discharge at the battery 104. The circuit 100 may include a first switching element, e.g., transistor 112, and a second switching element, e.g., transistor 114, with the first switching element connected to the power rail and thereby connected to the power supply 118 during charge and coupled to a capacitor 122 on the rail during discharge. The capacitor may have various functions including discharge signal conditioning as discussed in more detail below. The first transistor 112 may receive an input signal, such as pulse-width modulation (PWM) control signal 130, to operate the first transistor 112 as a switching device or component. In general, the first transistor 112 may be any type transistor, e.g., a FET or more particularly a MOSFET, a GaN FET, Silicon Carbide based FETs, or any type of controllable switching element. For example, the first transistor 112 may be a FET with a drain node connected to a first inductor 140, a source connected to the rail and a gate receiving the control signal 130 from the signal generator 110. In various embodiments, the circuit 110 also includes the inductor 140 but may also have various other possible inductive elements. The circuit 110, and particularly the combination of inductors 142, 140 and capacitor 148, when operating in a bi-directional fashion for both charge and discharge and as described in more detail below, may be considered a boost topology when controlling current from the battery during a discharge portion of heating or more generally during sinking current to a load during normal operation.

When heating, the system may be operated to both source current to the battery (generally referred to as charging but recognizing that during heating, the system optimizes source current to heat rather than charge) as well as sink current from the battery (discharging, similarly recognizing that during heating, the system optimizes current from the battery to heat rather than powering a load). The system may control the heating sequence to transition quickly from sourcing current to the battery and sinking current from the battery. For sourcing current (charging), the control signal 130 may be provided by the circuit controller 106 to control the operation of the first transistor 112 as a switch that, when closed, connects the first inductor 140 to the rail 120 such that a current from the power supply (and/or sourced from capacitor 122) flows through the first inductor 140, as well as a second inductor 142 if present, to the battery. The second transistor 114 may receive a second input signal 132 and may also be connected to the drain of the first transistor 112 at node 136. In a charge situation and in some instances, the second input signal 132 may be a PWM signal opposite of the first control signal 130 to the first transistor 112 such that switching is coordinated with one on while the other is off.

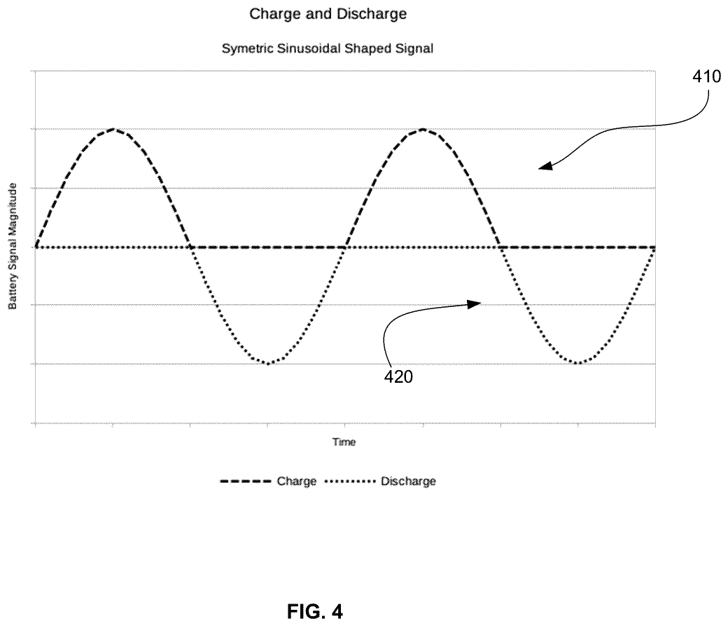

The inductor value or values, the capacitor value or values, the time and frequency of actuating the transistors, and other factors can be tailored to generate a waveform and particularly a waveform with controlled harmonics to the battery for heating the same. With reference to the example signals illustrated in FIGS. 4-6, the signal at node 136 when sourcing current may be a series of pulses between 0 volts and the about the rail voltage. The pulses at node 136 may be of varying duty cycle and may be generated at varying frequency. Overall, however, the pulses are generated to produce a signal that is the same or nearly the same as the intended current signal to or from the battery. So, for example, a signal like any of those in FIGS. 4-6 would be at node 138 based on the combination of pulses present at node 136, which are then shaped into the signal at 138 by the filter arrangement 110. Depending on the signal, 10s to 1000s (or more) pulses may be generated to form the desired charge signal.

A discharge sequence involves having the upper, first transistor 112, initially off and turning on the bottom, second transistor 114. The second transistor may be blipped on for only enough time to initiate current flow from the battery to the inductors 142, 140. The transistor may be controlled to eliminate or minimize current flow to ground through the second inductor. When current (discharge) from the battery is initiated, the second transistor is turned off and the upper transistor 112 is turned on, with either the power supply off or on, to drive current to the rail capacitor 122 and/or to a load 144. Once current flow is initiated from the battery, pulses may be controlled at node 136 to similarly shape the discharge signal or discharge portion of the signals. Depending on the type of power required by the load, the system may include some form of power conversion 146. The system may work with the power supply on or off. If off, current is directed to the capacitor and/or the load. If on, the power supply may include functionality that will coordinate the power supply to maintain rail voltage and if the discharge to the current increases the rail voltage above some level, it may synchronize the power supply to maintain the set rail voltage.

Overall, the system may be controlled, during heating, to quickly transition between sourcing and sinking energy to and from the battery. Moreover, the circuit may be operated to shape the current to the battery and/or shape the current from the battery by controlling the pulses at node 136. Through these features, alone or in various combinations, the battery may be heated to a sufficient level for charging to occur. It should be recognized that various different battery types have different temperature thresholds for proper operation including charging or powering a load. Additionally, or separately, heating may occur with little or no charge to the battery with energy instead focused on heating, minimizing, or avoiding plating or other electrode damage, transitioning to charging and altering the signal to one of optimal charging and transitioning to not generating excess heat, optimal circuit efficiency using components having multi-functional roles of controlled heating and controlled charging, among other benefits.

As introduced, the system may include a first capacitor 122 connected between the power rail and ground. The capacitor may be used to store discharge energy which then may be used to power the load while on charge, alone or in conjunction with power from the power supply. As discussed in more detail below, the capacitor 122 may also serve to condition the discharge signal prior to it being further processed by the power conversion or directly powering the load. Additionally, some of the energy required for a charge waveform may be provided by a combination of the power supply and the capacitor 122. In some instances, discharge energy from the battery stored in the capacitor may be returned to the battery during heating and when the system is sourcing current to the battery. The circuit may also include a second capacitor 148 connected between the first inductor 140 and the second inductor 142 to ground. The second inductor 142 may be connected to the battery, e.g., an anode of the battery 104.

After heating and during charging or powering the load from the battery, the system may operate, in general, to prevent rapid changes to the signal applied to or from the battery 104. In charging operation, the filter may also convert the pulses at the input of the filter to a charge signal as well as filter any unintended high frequency noise from the battery. For example, upon closing of the first transistor 112 based on control signal 130, first inductor 140 and second inductor 142 may prevent a rapid increase in current transmitted to the battery 104. Moreover, the inductor 140 or inductors 140 and 142, alone or in combination with capacitor 148, may shape the waveform applied to the battery, and control of the signal applied to the inductor(s) may provide for controlled shaping of the waveform. These components may similarly be used to control the discharge waveform shape. In another example, capacitor 148 may store energy from the power supply while first transistor 112 is closed. Upon opening of the first transistor 112, which may be accompanied by closing transistor 114, the capacitor 148 may provide a small amount of current to the battery 104 through second inductor 142 to resist an immediate drop of current to the battery and may similarly be used to controllably shape the waveform applied to the battery, particularly avoiding sharp negative transitions during conventional charging after heating. The filter circuit also removes other unwanted signals such as noise which may include relatively high frequency noise.

It should be appreciated that more or fewer components may be included in the system. For example, one or more of the components of the filter circuit may be removed or altered as desired to filer or define the signals to and from the battery. Many other types of components and/or configurations of components may also be included or associated with the system.

FIGS. 4-6 illustrate alternative possible example heating waveforms. In each case, the controlled waveform transitions between a charge or sourcing portion 410 (510, 610) to a discharge or sinking portion 420 (520, 620). At a high level, the heating waveform of FIG. 4 appears as a sinusoid with the positive going portion of the waveform being a current into the battery (e.g., the current path to the battery of FIG. 1) and the negative going portion of the waveform being a current from the battery (e.g., the current path from the battery to the capacitor on the rail of FIG. 2 or 3, noting the current path to ground through the lower transistor is only meant to initiate the discharge current path to the rail capacitor). The shape of either the current to the battery or the current from the battery is controlled by pulses at node 136. Namely, by controlling the frequency, pulse width, and/or voltage level of the pulses, the system can shape the waveform to or from the battery.

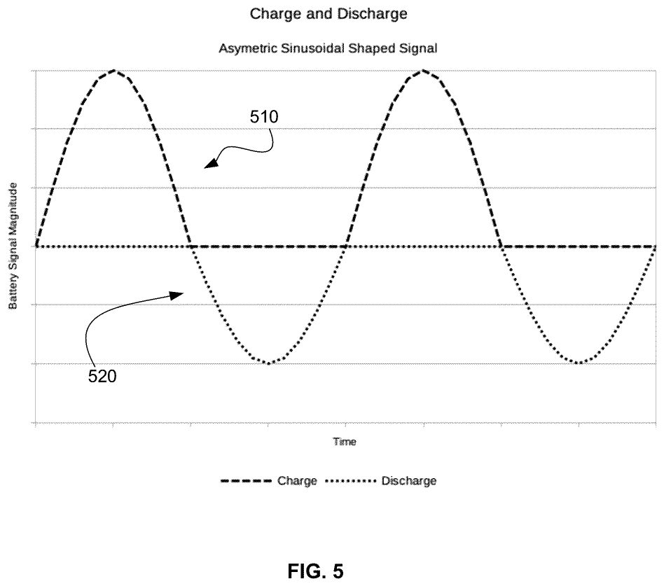

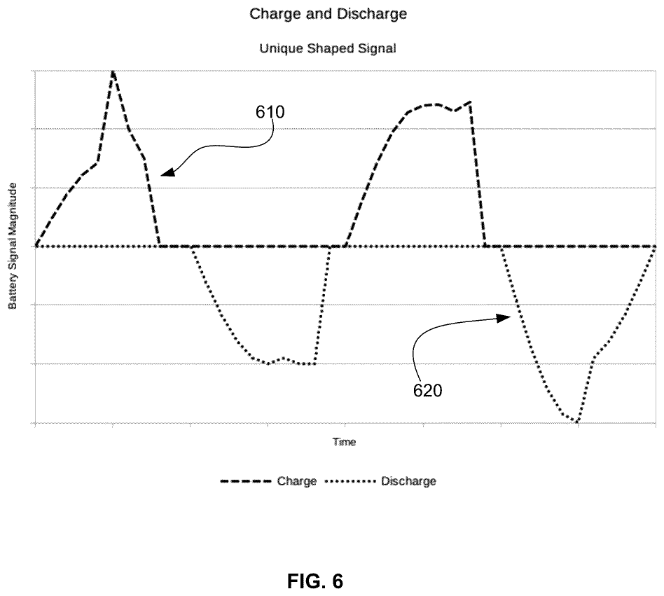

The heating waveform of FIG. 5 is of an asymmetric sinusoid with the current to the battery (positive going portion of the waveform) having a greater absolute amplitude as compared to the current from the battery. In some instances, particularly in a fully or nearly fully discharged battery, it may be necessary to add slightly more energy than is discharged to avoid over-discharging the battery. The heating waveform of FIG. 6 has arbitrarily, albeit controlled, shapes of the current to the battery as compared to the current from the battery. Moreover, the shapes are not consistent from one arbitrarily shaped input current portion to the next arbitrarily shaped input current portion as well as from one arbitrarily shaped output current portion to the next output current portion.

The frequency of transition from source to sink, the signal shapes of sourcing versus sinking, and various other aspects of the heating sequence may be varied. The shape of any portion of the signals, whether to or from the battery, may be based on the impedance of the battery to the signal being applied to or from the battery. The signal definitions may be preset. The signal definitions may also be algorithmic depending on various battery parameters including SOC, temperature, number of cycles, battery chemistry and configuration and numerous other possible attributes. The signal definitions may also vary through the course of heating and charging. As noted herein, impedance and harmonics may affect the charge signal choice or definition. As a general notion, signal definitions associated with relatively higher impedance and associated harmonics may be selected for a heating sequence with relatively lower impedance and associated harmonics for a charging or discharging to power a load sequence. It should also be noted that the relatively rapid change between sourcing and sinking current to and from the battery may be used to heat, with the system transitioning away from sinking current (during charge) once a sufficient temperature is reached such that charging will not damage the battery.

In a heating sequence, it is possible to tailor one or more attributes of a charge and/or discharge portion of a signal to a relatively higher impedance characteristics as compared to a charging sequence where it may be optimal to tailor the charge signal to relatively lower impedance characteristics. By injecting current briefly into the cell followed by pulling current briefly from the cell, it is possible generate heat without initiating any substantial battery charging. The frequency of transition between current into and out of the battery may affect the optimal heating if the harmonics associated with the transition are relatively high such that energy is used primarily to heat. Additionally, or alternatively, the charge or discharge portion of the waveform may be defined to include harmonic attributes associated with a relatively high impedance. As such, current energy into the battery or out of the battery may be consumed primarily as heat due to the relatively higher impedance (resistance generally) as opposed to charging, charging a capacitor during discharge and/or powering a load during discharge.

Battery temperature may be assessed in various ways. In one example, the system may assess battery temperature using a temperature sensor at the battery. Various temperature sensors may be employed either in contact with the battery, in contact with a terminal of the battery, positioned in a housing containing the battery, or otherwise. Various sensor examples include thermistors, thermocouples, infra-red sensors, diodes and transistors, or any of a myriad of different types of temperature sensors.

In another example, the batteries response of harmonics or other frequency attributes may be used to probe the internal temperature of the battery or more generally the ability of the battery to accept charge, which may be the same or slightly different than a measurement of temperature, particularly the external temperature of the battery. The use of harmonic response may also be used to more uniformly assess the capability of the battery to accept charge.

In one specific example, the system uses a characterization of the battery response to various harmonics at different temperatures. Any given battery type or specific battery may be characterized. The characterization may be stored in a look-up table accessible in memory by the processor, by setting thresholds, or the like. In this specific example, it is understood that various different battery chemistries and configurations have different impedance responses at different temperatures. Thus, for a given battery, the impedance response of signals with the specific harmonic frequencies applied to the battery differs based on temperature. In some instances, temperature probing signals of at different discrete frequencies may be used to generate an impedance response, which is then compared to the characterization to assess temperature or more generally the ability of the battery to accept charge, and thus whether or not heating is required before charge may be initiated. The impedance response may be characterized by the imaginary, real or both imaginary and real components of impedance. In some embodiments the impedance response may be used alone or in combination with a sensed measurement of the battery temperature to determine whether the battery should be heated or may be charged. Similarly, other frequency-based responses or impedance derived terms such as susceptance, admittance and capacitance may be used alone or in place of a direct sensed measurement of temperature to determine whether the system will be configured to heat the battery.

In general, in various embodiments where impedance values are being considered, the technique assesses harmonic values where the values, alone or in combination, are associated with some impedance. Given the generally inverse relationship, the term impedance as used herein may include its inverse admittance, including its constituents of conductance and susceptance alone or in combination.

In another aspect, battery heating may be achieved through controllably charging or discharging the battery, or a combination of the same as discussed above. In this example, the signal, whether or a charge signal, a discharge signal, or a signal alternating between charge (sourcing current to the battery) and discharge (sinking current from the battery), is composed of one or more harmonics tuned such that signal optimizes relatively high conductance and relatively high reactance in the battery. Using a charge signal as an example, the optimized combination (or balance) between high conductance and high reactance generates heat in the battery. In this example, the signal is composed of harmonics such that the harmonics may be identified in a frequency domain representation (or transform) or representations of the signal. The tuned signal may also be shaped to reflect various harmonic attributes. In a fairly simple example, the signal may also be composed of a discrete sinusoid at a specific frequency such that it both composed of the harmonic and shaped in the form of the harmonic. Generally speaking, even with very high conductance, if the reactance is too low then the magnitude of the signal may be higher than many charging environments can support in order to create sufficient heat. Similarly, if the conductance is too low, then even with high reactance, too large a conversion of energy into heat may be required. Hence, for any starting temperature and battery chemistry, the system selects a charge signal with harmonics that balances high conductance and high reactance.

In one specific example, a given form of battery may be characterized at various temperatures by assessing signals composed of various combinations of harmonics to identify a signal or signals that balance relatively high conductance and relatively high reactance to achieve sufficient heating. Characterization may also determine the time at which a heating signal is applied to reach a state sufficient to begin heating. The balance may further account for attributes that minimize energy used for actual charging, so the energy is instead focused on heating. The same technique may be applied to generating discharge signal harmonics, which may be the same or different as the charge signal at various temperatures.

The harmonic frequencies may typically be relatively higher frequencies than the kinetic and diffusive processes in any given battery that the signal is optimized to heat. Generally speaking, frequencies are selected that are faster than the kinetic response of the electrochemical processes so that the voltage and current magnitudes do not adversely impact the electrodes or interfaces of the battery when heating occurs. Thus, in heating, it would be possible to use a relatively higher voltage signal (e.g., 6V when normally a maximum of about 4V is specified) that would normally cause plating, but because the signal is composed of a harmonic or spectrum of harmonics that are faster than the kinetics, the relatively higher voltage will not cause plating. With that said, in many instances, a signal is chosen that falls within relatively lower specified charging (or discharging) voltage levels. Additionally, with the various heating techniques described herein, in some instances the system is optimized to heat without passing any net charge. In such instances, the system controls the signal to charge and discharge with relatively even total energies such that the signals cancel each other, accounting for any differences in energy conversion efficiency differences between the charge and discharge portion at any given temperature.

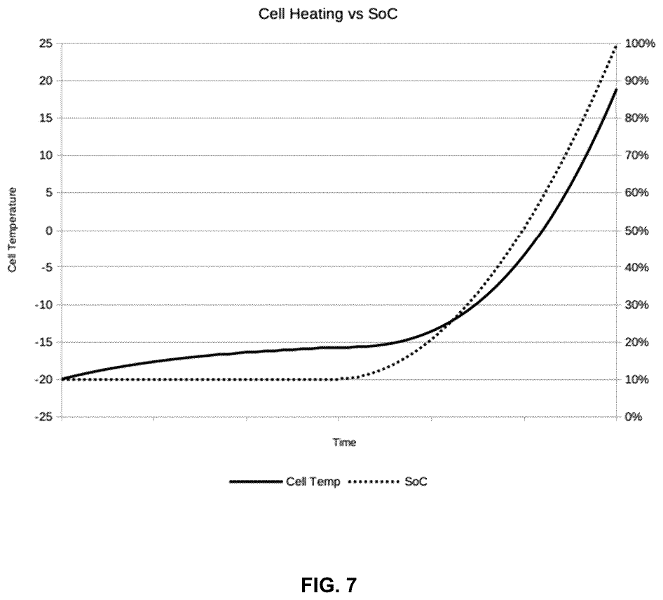

FIG. 7 is an example of a profile that heats the battery until the battery temperature will allow charging. In this example, the initial battery temperature is −20 C, at 10% SOC. The battery is heated until it reaches about −15 C, at which time this battery may begin charging. It can be seen that the SOC stays at about 10% as the battery is warmed about 5 C before charging commences. It can also be seen that the temperature of the battery continues to rise until it reaches 100% SOC.

In many conventional battery powered systems, the system relies on a DC discharge current from the battery to provide power to some load. The battery may be a single cell or small number of cells such as in a power tool, vacuum, portable speaker system or the like, or a large pack of interconnected cells such as may be found in an electric powered vehicle of some type. The arrangement and type of cells will typically depend, at least in part, on the specified capacity for the system in which the battery is operating, the required discharge currents for the load of the system and other factors. Regardless, conventional batteries provide a DC discharge current when powering a load. When an AC signal is required to drive a load, such as an AC motor, a converter, such as converter 146, is used to convert the DC output of the battery to the required AC signal for the load.

For battery heating and to control charging based on heating, and to define the shape of the harmonically-tuned charging signal during or after heating or otherwise, aspects of the present disclosure involve a unique battery charging and heating sequence based on starting temperature and the projected change in temperature of the battery during charging. Aspects of the present disclosure further involve a technique to shape a charge signal for optimum charging, whether heating, charging or some combination of heating and charging. The charging signal may have a harmonically-shaped leading edge. Stated differently, the leading edge of charge signal may be defined by the frequency of a sinusoid and may have a corresponding shape. Aspects of the present disclosure further involve, alone or in conjunction with either or both of the heating sequence and the shaped charging signal, a method of determining a maximum charging current that can be applied based on the current state of the battery and accounts for battery heating and/or battery temperature.

In one aspect, a charging system is configured to assess battery temperature and determine a charge sequence based thereon. As discussed above, in some situations, the temperature of the battery may be at or below some threshold where charging may damage the battery or may simply be ineffective. In such a situation, the system may generate a signal to warm the battery. As noted above, various possible warming signals are possible. As the battery temperature rises above the threshold, the system may begin to charge the battery while continuing to warm the battery. Finally, above a second threshold, the system may discontinue warming and transition to a signal only intended to charge the battery. It should be recognized, however, that charging a battery tends to warm the battery. One benefit of the harmonically tuned charging signal is that it optimizes energy use for charging thus less heating may occur as compared to various conventional charging techniques. As such, during charging, it may be possible to source more current than conventional system because the charging techniques generate less heat, among other advantages.

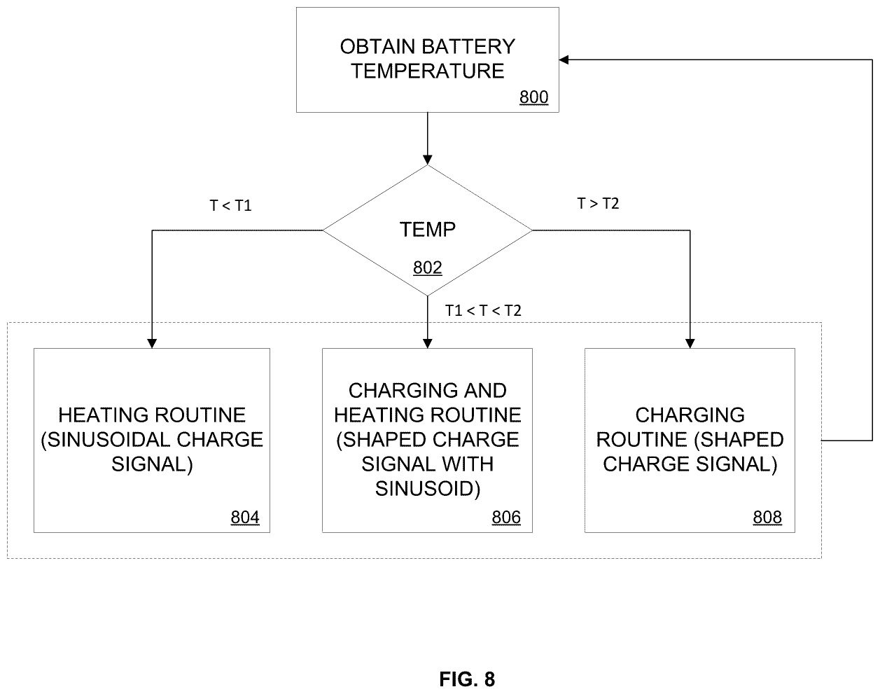

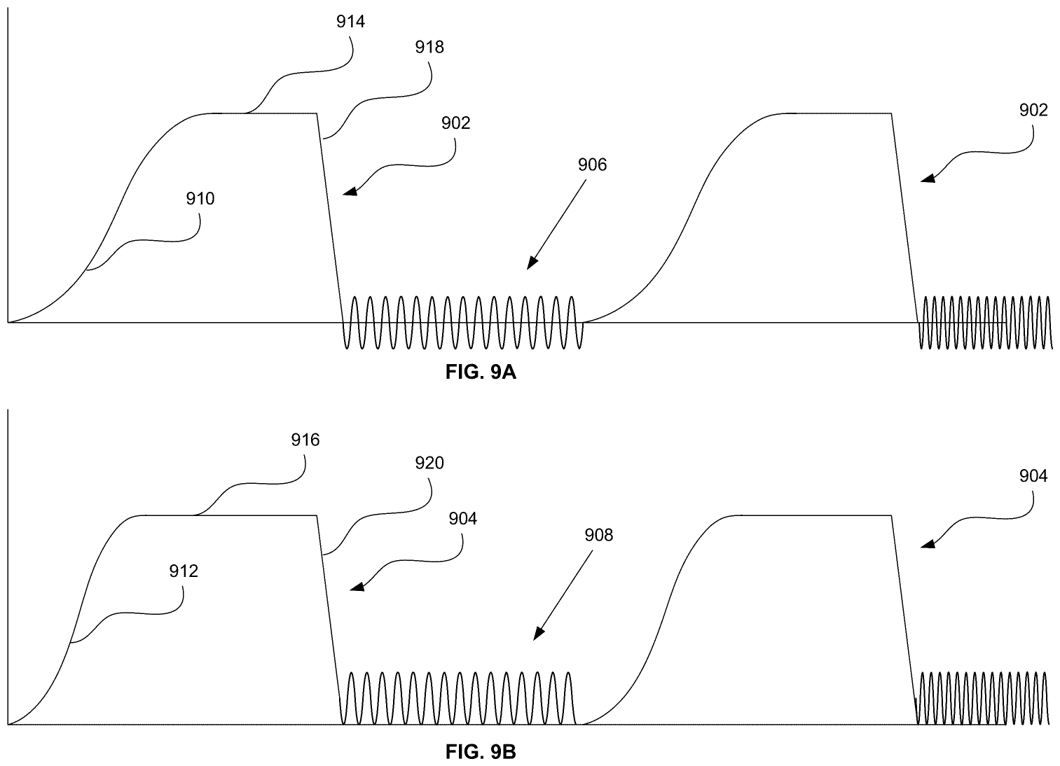

Turning now to a particular method of heating a battery, FIG. 8 is a flow diagram illustrating one possible example of a method of heating a battery, with FIGS. 9A and 9B illustrating possible examples of a combined charging and heating signal. The magnitude of the current for the signals of FIGS. 9A and 9B will depend upon cell capacity and outside temperature. For example, for some cell types, the current will be about 6 A to 12 A peak to peak for 3 or 4 Ah cells. In some cases, higher magnitudes for heating are possible and would heat the battery faster (as compared to lower magnitude signals). Higher magnitudes than specified for charging are possible and such magnitudes could potentially be relatively large since heating frequencies may be selected that are not impacting electrochemical processes—e.g., signals at currents of 60 App or more.

With reference to FIG. 8, to begin, a charging system obtains the battery temperature (operation 800). Battery temperature may be obtained in a variety of ways. As discussed above, battery temperature may be obtained from one or more temperature sensors positioned in or at the battery (or a battery pack, in which case more than one temperature sensor may be used). In addition to battery temperature, the system may also obtain ambient temperature (environmental). It should be recognized that besides a sensed battery temperature, battery temperature may also be computed from other information.

Depending on the battery type, the system may recognize a first temperature T1 at or below which the battery should be heated prior to charging, a temperature range, which may be between the relatively lower first temperature T1 and a second relatively higher upper temperature T2, between which the system may begin charging and the system may also continue heating, and the upper temperature T2 above which heating is no longer required and the system may charge without continued purposeful heating. For purposes of example, the method and system is discussed with reference to effectively three temperature zones at or below T1, between T1 and T2, and at or above T2; however, it should be recognized that the method and system may include more or fewer zones, with various heating and charging actions being modified accordingly. For example, the intermediate zone may be broken into sub zones in which the system transitions between effectively more heating to effectively less heating, and transitions from effectively less charging to effectively more charging as the system overall transitions from the first state where the system is only heating to the third state where the system is only charging. Regardless of breaking the intermediate zone or state into sub zones, in the intermediate stage, the system may charge at a lesser rate than in the last stage where the battery has risen to a temperature where charging may proceed without additional heating. Regardless, in one specific example, the system determines, from the obtained temperature T of the battery, what mode to initiate—heating, hybrid heating and charging, or charging (operation 802).

In the first mode (operation 904), when the temperature is too low for charging (e.g., when T is at or below T1), the system accesses a signal used only for heating. Examples of such signals are discussed with reference to FIGS. 4-6 as examples and may be provided by a circuit such as illustrated in FIGS. 1-3. In one specific implementation, the heating signal is a sinusoidal current waveform as generally shown in FIG. 4. The current waveform is centered at zero current with alternating sinusoidal positive 410 and negative 420 currents. The frequency of the sinusoid may be selected based on battery type and through battery characterization and testing. One objective of the alternating heating waveform in the form of a sinusoid centered on zero current or if other shapes, when the temperature is considered too low to charge without potentially damaging the cell, is to first heat the battery without any meaningful net charge among other things discussed above.

The method is discussed from the perspective of beginning with the first mode (operation 804), checking temperature and then proceeding to the second mode and then the third mode, based on battery temperature. It should be recognized that the method may start first in the second or third mode depending on starting temperature. Additionally, in some arrangements, the heating sequence may be initiated for a period of time as opposed to when the battery reaches some temperature (e.g., T1 or T2). Thus, for example, if the initial temperature is below T1, then the system may initiate the heating sequence for a period of time and then transition to the hybrid mode two, discussed below, or simply bypass the hybrid mode and move to full charge mode three in an implementation without an intermediate mode or should the timing be set to not involve an intermediate mode. It should be noted that other thresholds besides battery temperature are also possible (e.g., time or current applied, time in an ambient temperature, modeling, and combinations of the same). Similarly, while the method is primarily discussed relative to reaching different threshold temperatures T1 and T2, the system may act when the temperature is reached, when the temperature reaches some range around the temperature, and the like.

It should be recognized that other heating signals may also be used in the first mode. In a situation where a charge sequence is first initiated when the temperature is below T1 and hence the heating mode is first initiated, depending on temperature, it is possible to transition from a sinusoid centered at zero to a sinusoid with some positive DC offset such that some charging is initiated or to start at a sinusoid with some positive DC offset or otherwise greater positive charge energy such as in the signal of FIG. 5. The signal may then transition to the second mode, discussed below, when the temperature T1 is reached and the battery warms past T1 or even a second temperature where the system transitions to a full charge sequence.

Continuing with the example of FIG. 8, when temperature T1 is reached, the system may transition to the second mode. In the second mode, when the battery temperature falls within some range (e.g., T between the temperature T1 and the temperature T2), the system may use a hybrid charge signal, examples of which are shown in FIGS. 9A and 9B. The hybrid charge signal may include a charge portion 902, 904 and a heating portion 906, 908. The examples show a repeating pattern of charge portions followed by heating portions. However, a hybrid signal may include any sequence of charge portions and heating portions. For example, a hybrid charge signal may include a sequence of some number of charge portions (e.g., 902 or 904), followed by a heating portion (e.g., 906 or 908), and then a subsequent sequence of heating portions. In such an example, each charge portion would begin where the proceeding charge portion ends. Similarly, the length of the charge portions and the heating portions may vary. For example, near temperature T1, the heating portion may be relatively longer than the charge portion as compared to when nearing temperature T2 where the charging portion may be relatively longer (or a series of charge portions (which may include intervening rest periods) occur before a heating portion) than the heating portion or some heating portions may be replaced with rest periods, which are discussed below and elsewhere herein. In the examples of FIGS. 9A and 9B, a rest period would involve transiting 918 (920) from the charge portion 914 (916) to a rest period with no charge or discharge current (or substantially no charge or discharge current), the rest period occurring where the heating portion 906 or 908 is shown, and then to another charge portion 902 or 904. Similarly, the hybrid signal may include less relative charge energy near temperature T1 and more relative charge energy near temperature T2. Similarly, the hybrid signal may change, dynamically or programmatically, as temperature increases between temperature T1 and T2. Similarly, the signal definition may be governed by the starting temperature, such as if the starting temperature falls somewhere with the range of T1 to T2.

In the examples illustrated, the charge portions 902, 904 of the hybrid charge and heating signal includes a sinusoidally shaped or otherwise more generally a shaped non-abrupt leading edge 910, 912 followed by a body portion 914, 916, which terminate at a falling edge 918, 920. The leading edge (e.g., leading edges 910 or 912) in many instances may not be an immediate very high frequency edge, such as in a square wave, to avoid injecting high frequency harmonics into the battery when the charge portion of the signal is initiated. Referring to FIG. 9A, the heating portion 906 falls between charge portions and is defined by a sinusoidal heating signal centered about zero amps. As such, the sinusoid oscillates between a positive (charge) current and a negative (discharge current). In some examples, the heating signal provides about a net zero capacity difference, with the energy during the heating portion of the hybrid signal primarily going to heating with little or no net energy charging or discharging the cell. The heating portion of the charging signal discussed in FIG. 9B, has some DC offset and is discussed in more detail below.

In various possible examples, the range of frequencies for the sinusoidal heating portion of the hybrid signal or the heating only signal (discussed earlier) may be 1 KHz to 100 KHz. The range of frequencies, depending on the cell and particular conditions, may also fall below 1 KHz, such as in the range of 100 Hz to 1 KHz. Similar, in some circumstances, frequencies above 100 KHz are possible. In one specific example of a 3000 mAh Lithium-Ion rechargeable cell with a 35 A specified maximum discharge current, and a 4 A specified current at 4.2 V for conventional CCCV charging, the heating sinusoid may be 10 KHz and cycle between −10 A and 10 A (with such a cell, the temperature T1 may be about −10 C and the temperature of the cell may reach 5 C at T2) Heating as described in this example and other herein provokes the maximum possible internal heat generated from contributions from resistive and susceptive mechanisms. Susceptance due to the coiled electrodes results in magnetic fields which are absorbed by magnetic elements in the cathode, allowing them to participate in heat generation in parallel to I²R heating through the current collectors. It should be recognized that such a relatively high current is not typically specified at relatively low temperatures. For example, for the same type of cell, a conventional charge (if allowed) would be on the order of about 2 A. However, as noted above, the energy of the heating portion of the signal is primarily to heating allowing higher currents than if only charging. The frequency and positive and negative current values of the heating signal will vary depending on the type of battery, the capability of the charge circuitry, the capability of the power supply and other factors. While the heating sinusoidal signal may be symmetrically positive and negative (e.g., cycling between +10 A and −10 A), it is also possible to have a non-symmetrical signal. It is also possible to center the sinusoid at a positive DC offset (e.g., shown in FIG. 9B) such that there is some net charge during the heating portion, or to transition from a zero centered sinusoid to some non-zero positive offset sinusoid as the battery warms through the temperature zone between T1 and T2. It is also possible to run mode two for a set period of time or to run modes one and two, sequentially and in combination, for some set period of time with the transition from the first mode to the second based on time. Besides time and temperature, other thresholds may be used to transition between signals such as environmental temperature, net current to the battery, using other measurements like voltage as a proxy for temperature, and the like.

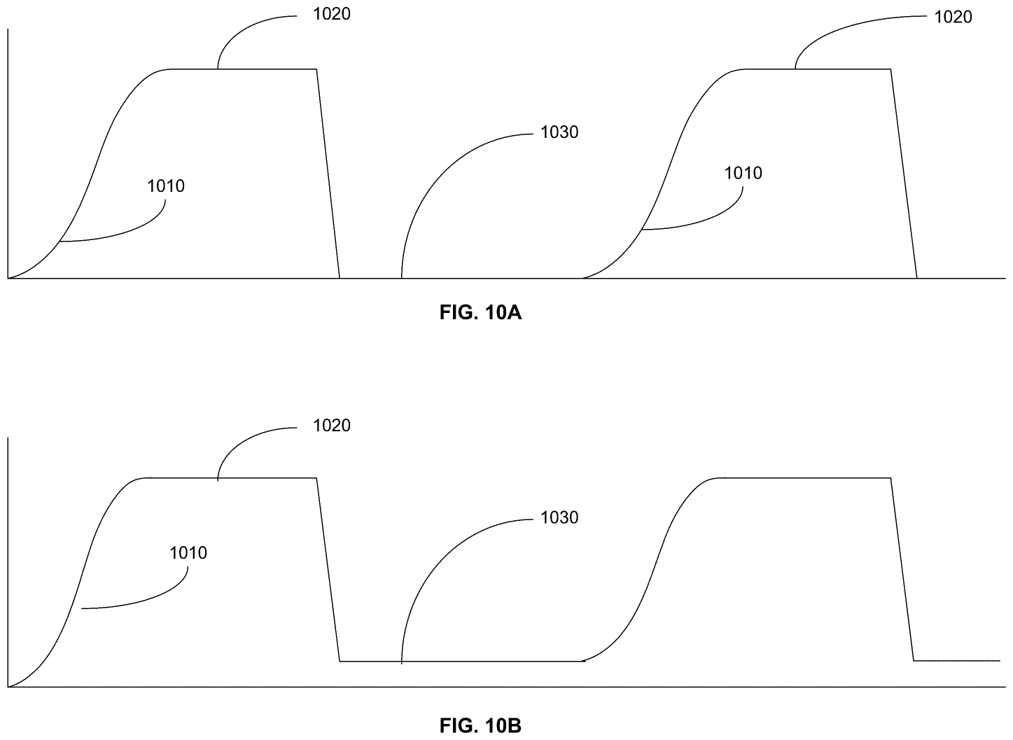

The third mode (operation 808), when the battery temperature T is at a sufficient temperature T2 to charge without additional heating, the system transition to a charging sequence. In various aspects and referring first to FIG. 10A, the charge signal 1000 includes a shaped leading edge 1010, a body portion 1020 and a rest portion 1030. In the hybrid signal or the charge signal, the shape of the leading edge may be that of a sinusoid at a frequency selected based on a relatively low impedance harmonic frequency. The sinusoidal leading edge is followed by a relatively steady charge current (e.g., the body portion 1020) terminating at a falling edge. Unlike the hybrid signal, the falling edge is not followed by a sinusoidal heating portion but is instead followed by a rest period 1030. The rest period may be zero current or may be some non-zero DC current (see, e.g., FIG. 10B) less than the current of the body portion. The peak current of the body portion may be in the range of 10 A to 60 A depending on the type of cell with the rest current in the range of 0 A to 10 A. Values for peak current, rest current, and other values may vary, as noted elsewhere herein, depending on temperature, the type of cell, circuit capabilities, state of charge, and other factors. In this example, if non-zero, the rest current may be less than a specified charge current if using conventional CCCV charging. If, for example, the charge current using CCCV charging is around 4 A at 4.2 V, the rest current may be 2 A or less.

In some examples, a heating signal may be applied to maintain a battery in some operable range. The signal may be applied when the battery temperature falls below some temperature threshold, even when the battery is otherwise fully charged. Since frequencies may be selected where no net charge is applied to the battery, heating may be maintained without exceeding an upper charge threshold. Alternatively or additionally, the system may charge and discharge the battery within some small window, e.g. 99%-100% percent while also generating a heating signal to maintain a battery temperature. In various examples, when connected with a charger, the system may maintain battery temperature in a range optimal for use powering some load and to avoid the battery falling below some operable threshold when the battery is in an cold ambient environment that may otherwise cool the battery below or otherwise into suboptimal operating temperature ranges.

With regard to the various modes and otherwise, the various heating, hybrid charging and heating, and charging signals may be generated using the circuits depicted in FIGS. 1 through 3, and otherwise.

As noted herein, a charging signal or hybrid charging and heating signal may include a shaped leading edge, a body portion and a rest period noting that rest period may also include a heating sinusoidal overlay. The described charging technique and charging signal is not a conventional constant current constant voltage type charging where, in essence, a specified constant charge current is applied until the battery voltage begins to rise, at which time the charge current is reduced. The charging technique is also not pulse charging as the charge signal defines a specifically shaped leading edge; in fact, high frequency harmonic content square pulses are typically avoided for charging due at least to high impedance to the uncontrolled high frequency harmonic content of square pulses, particularly when the pulse first initiates.

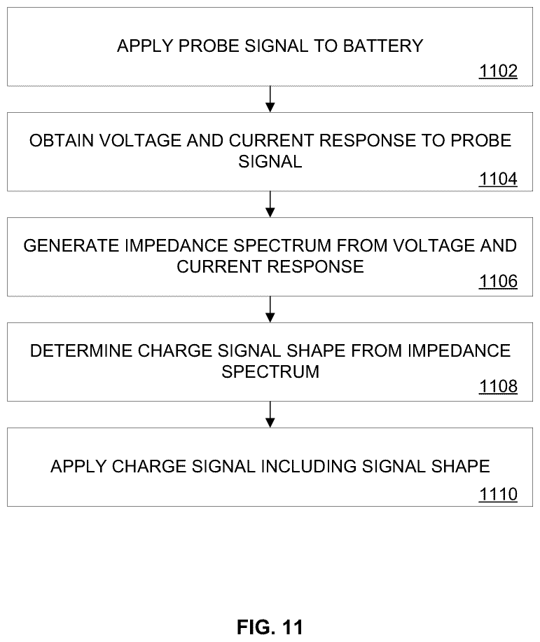

Referring to FIG. 11, a method of generating the shape for the charging portion of a signal (e.g., a hybrid charging and heating signal or the charging signal) involves obtaining an impedance spectrum for the battery, and from the impedance spectrum selecting a frequency at which the impedance is relatively low and using that frequency to define the shaped-leading edge of the charge portion of a signal. In one example, the system uses or otherwise references imaginary impedance (reactance) values. The shaped leading edge and overall signal may be generated using the circuits depicted in FIGS. 1 through 3, and otherwise.

To obtain an impedance spectrum, in one possible example, the method involves applying a probe signal to the battery (operation 1102). The probe signal may include a spectrum of harmonics, which may be used by the system to assess the impedance of the battery to the various harmonics. The probe signal may be the charge signal or may be a dedicated signal. The probe signal may be interleaved during charging or run discretely at the initiation of charge, intermittently or periodically during charge, or otherwise. In one example, the probe signal may be square wave or square pulse. In one specific example, the probe signal is a square wave centered at zero amps. In one possible example, the probe signal is a square wave centered at zero amps, with a +4 V (positive) portion and a −4 V (negative) portion. Here, the mean current is 0 A. The duty cycle is 50%. The frequency, duty cycle, current or voltage magnitude or other attributes of a probe signal may vary depending on cell type, device type, temperature, state of charge and other possible parameters. These parameters may be determined based on characterization of any given cell type. In one specific example, the square wave probe is applied to the battery for a single period of about 30 msec. Stated differently, the probing signal may comprise a positive square pulse of some current and a negative square pulse of some current. The pulses may have the same duration, e.g., 15 msec each, or may have different durations. A probe signal may be only a positive pulse (current to the battery) or only a negative pulse (discharge current from the battery). Each pulse may include the same magnitude current or the pulses may be asymmetric. While other probing signals are possible, a square pulse or wave has harmonic content at a wide range of frequencies and is efficiently generated by a range of conventional charging hardware topologies. In general, the purpose of the probe signal is to very briefly and discretely introduce a wide spectrum of harmonic content into the battery in order to assess the impedance of the battery to various harmonics. Thus, whether a square wave or square pulses or other signals, the probe signal is intended to introduce, momentarily, a spectrum of harmonics to the battery. In the case of a square wave centered at zero amps, there may also be an equal magnitude current to and from the battery with little or no net charge effect. The idea is to probe the cell without altering its state of charge. Some net charge is possible and okay in situations where changing the SOC is similarly okay, e.g., at a SOC less than 100% and in a proper temperature form charging. Some negligible net charge from the probing signals is similarly okay when probing is infrequent and net charge is thus negligible. In some arrangements, it is possible to inject a range of different probes, containing different harmonic content. Even though uncontrolled and/or high frequency harmonics may have deleterious effects on the battery, the system is only applying the square pulses in a very short duration for the purpose of obtaining the impedance spectrum thereby substantially avoiding such effects.

In the presence of the probe signal, the system measures the current and the voltage at the battery terminals (operation 1104). The current and voltage signals are captured in the time domain. For each of the current and voltages measured in the presence of the probe signal, the system obtains a frequency spectrum from which the system may further generate an impedance spectrum (operation 1106). In one example, the system generates domain transforms of the current and voltages signals to produce a voltage frequency spectrum and a current frequency spectrum. The domain transform may be a discrete Wavelet transform using a Morlet wavelet. In some instances, the wavelet may also be considered a Gabor wavelet or complex Morlet wavelet. In one possible implementation, the system may use fixed point arithmetic to generate the impedance spectrum, which may allow for use of relatively lower cost and simpler microcontrollers or other computing platforms more typical of some charging environments where significant computational power is not otherwise necessary or conventionally available.

From the frequency spectrums of the current and voltage signals, the system generates the impedance spectrum (operation 1106). In one example, the impedance spectrum is generated from dividing the voltage spectrum by the current spectrum. More particularly, complex voltage values at various frequencies are divided by complex current values at the same frequencies to generate impedances at the various frequencies. This may generate a complex valued impedance spectrum. In some examples, it is sufficient to limit the generation of an impedance spectrum to a discrete range of frequencies, e.g., 200 HZ to 3 KHZ.

Regardless of the technique, the system generates an impedance spectrum that identifies the impedance of the battery to a particular frequency of a harmonic of a signal applied to the battery. So, in a simplified example, in a square pulse probing signal applied to the battery, there will be a number of harmonics. Through the technique discussed here, the system generates discrete impedances of the battery to some or all of the discrete harmonics in the probe signal. The spectrum, at a generalized level, shows the resistance of the battery to a particular frequency of charge signal. The battery may have more or less impedance (more generally resistance) to different frequency harmonics of the probe signal.

From the impedance spectrum, the system may identify a particular harmonic that is used to define the leading edge of the charge portion of the signal (operation 1108). To determine the shape of the leading edge of the charge signal, the system determines the optimal frequency from the impedance spectrum generated from the probe signal. In one particular example, the optimal frequency is the frequency associated with the lowest impedance (specifically, reactance in some embodiments) in the impedance spectrum. Thus, the system choses the frequency associated with the lowest impedance. It should be appreciated that there may be instances where the system can instead assess admittance, e.g., the highest admittance or the imaginary part of admittance—susceptance. In general, a charge signal applied to the battery with a shape of a frequency associated with a lower impedance will more efficiently transfer energy for charge as compared to frequencies associated with a higher impedance. The optimal frequency is then set as the leading edge of the charge signal or charge portion of the hybrid signal. So, the leading edge 1010 defines a portion of a sinusoid at the identified frequency as shown in the examples of FIGS. 10A and 10B.

Besides the shape of the leading edge of the charge portion, the system also determines the overall attributes of the signals including the length of time of the rest period relative to the charge time (including the shaped portion and the body portion), the overall signal period and other attributes. In one possible example, the period of the charge signal and the rest period are preset and based on battery characterization. The period of the charge signal includes the shaped leading edge and the body portion following the shaped leading edge. In various possible examples, the charging portion may fall in the range of 100s of microseconds to 10s of milliseconds. The overall period includes the charging portion and the rest period (or heating portion). The rest period (or heating portion) may fall in the range of 100s of microseconds to 10s of microseconds. In other possible examples, the period may fall in the range of 100s of microseconds to 10s of milliseconds. A peak current at the peak of the shaped leading edge and the body portion of the charge portion of the cell may be around 20 A but the peak current value depends on the cell type, temperature, characterization and other factors and thus may differ significantly from the example peak current. One example of determining charge current, including the peak current is discussed below.

The method of determining the shape of the leading edge may be repeated throughout a heating or charge cycle, periodically, intermittently, upon reaching various targets (SOC or otherwise) or otherwise. In one specific example, a probe signal and the following operations (1104-1110) are repeated about every ½% to 1% SOC change. In another example, probe signals and the following operations are performed over time, e.g., every 5 seconds, 30 seconds, or 60 seconds. The frequency of probing signals and subsequent operations may change over time. For example, as the cell is heating, the cell may change more quickly and hence the rate of probing etc. may change. As the cell nears a full charge, the rate of probing may also change.

Aspects of the present disclosure also involve a method of generating a current level for a charging signal, where the current level is set such that the battery does not overheat over the course of a charge cycle. The method may be used in conjunction with the techniques described herein such as through setting a current level for a shaped hybrid charging and heating signal or a shaped charging signal. The method may also be used to set current levels of any form of charge signal to account for battery heating that occurs during charging in a host of different charge situations, and not overheat a battery during charging, among other advantages alone or in combination.

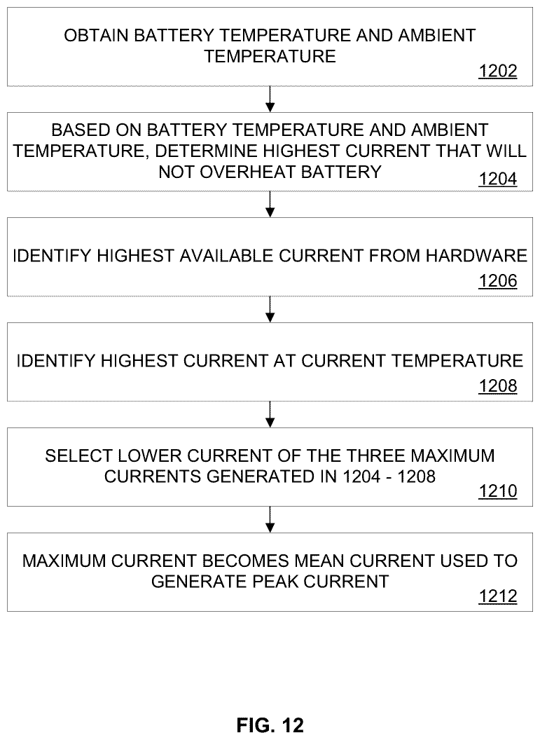

To begin and referring to FIG. 12, a method 1200 begins with accessing battery temperature and ambient temperature (operation 1202). The technique may account for battery temperature and ambient temperature, only battery temperature or other parameters. As noted herein, battery temperature may be obtained or more generally accessed in a number of possible ways. Ambient temperature may be obtained from a temperature sensor positioned to detect ambient temperature in the environment of the device including the battery to be charged. Ambient temperature may also be accessed from third party devices, e.g., some form of temperature sensor proximate the device to be charged with a temperature signal available by way of some signal (e.g., Bluetooth or WiFi) or the like. Ambient temperature in some arrangements may be obtained by way of a network connection such as from a third-party service accessible over a network connection. In any event, the system may access one or both of battery temperature and ambient temperature. The system may also access a projection of ambient temperature over time.

The system then, using battery temperature and ambient temperature, obtains a maximum current for charging the battery (operation 1204). The maximum current is a current at which the battery, if charged at or below that maximum current, will stay below a maximum threshold temperature during charging. The maximum threshold temperature may be a specified maximum temperature above which charging is discontinued, for example. The maximum threshold temperature may also be some other specified maximum temperature that the system seeks to not exceed.

The maximum current may account for state of charge, and may identify a charge current that, when applied to a battery, will not cause the battery to heat above the maximum threshold temperature at the end of the charge cycle. So, for example, at the same temperature, the maximum current may be higher if the starting state of charge is relatively higher as compared to a relatively lower maximum current if the starting state of charge is lower.

In one example, the system accesses a model, which may be in the form of an equation (e.g., a quadratic equation including a variable for battery temperature and a variable for ambient temperature). The model may also be a look-up table that receives a battery temperature and ambient temperature values as keys and identifies a charge current value based on the keys. The model may be based on battery characterization, in one example, that identifies temperature profiles of a battery across a spectrum of charging situations and how those charging situations affect battery temperature.

In response to the battery temperature and ambient temperature, the model produces a charge current maximum value. In one example, the model may presume a fully discharged state and the identified charge current value represents a current at which the battery may be charged to a fully charged state and not exceed the maximum threshold temperature. The system may also accept the state of charge and generate a current number to reach fully charged without exceeding the threshold temperature. In such an example, the current value may be slightly more than it would be from a fully discharged state. One advantage of a technique not accounting for state of charge, is the system may operate in a way that will default to a current that will not exceed the temperature threshold and does not require access to an accurate ongoing state of charge assessment, which may be beneficial in various circumstances such as when a battery is first put on charge and a current or accurate SOC is not available.

The system uses ambient temperature to account for the environment of the battery and its effect on battery heating. In one example, the maximum current is set at the beginning of a charge cycle and is not updated during the charge cycle. In another example, the system may update a maximum current value based on time, state of charge progress, changes to ambient or battery temperature, and other measurements. In another example, the maximum current value may be one value among other values used to determine the charge current at any given point in a charge sequence.

It should be noted that the maximum current or any other current value may be limited by the capability of the charging environment. Thus, the system may also access a current limit value based on the charging environment (operation 1206). In some instances, the charging hardware itself may be limited in the amount of charge current it can source. For example, a system may be able to charge from a higher current source but is connected with a lower current source limiting the maximum charge current the system can provide. In other instances, other limits may be imposed on the system that dictate a current limit available to charge the battery. For example, charging hardware may be limited based on limits of a power source. Regardless, the system may account for a system-based current limit. This becomes relevant if the maximum current from operation 1204 exceeds the system current limit, then the system current limit effectively becomes the maximum current.

Finally, the system may access a third current parameter associated with the amount (e.g., maximum) charge current to the battery based on its current temperature (operation 1208). As noted herein, batteries below or within certain temperature thresholds cannot be charged at the same rate as when above the threshold or range of thresholds. As the battery is warmed, higher charge currents become available. Any given battery type may be characterized to identify a maximum charge current that may be applied, without damaging the battery, based on its temperature. As noted herein, temperature plays a role in the ability of a battery to receive charge. In this example, the system accesses a model that determines the maximum current at the present time based on present battery temperature. Where the current limit discussed above identifies a maximum current that can be applied to maintain the battery at or below some threshold in the future (e.g., when the battery reaches a full state of charge), the model in this instance identifies a maximum charge current that the battery can accept at the present time based on its current temperature. The value may change as the battery warms. Additionally, if the value is below a threshold (e.g., T<T1 discussed above), then the model will indicate that no charge current be applied until the battery reaches or exceeds the threshold.

So, in summary and in one example, the system may identifies three maximum current limits: (1) a first current limit that is the maximum current, given the battery temperature and ambient temperature, at which the battery may be charged and not exceed some temperature in the future; (2) a maximum current that the system can support; and (3) the maximum charge current that may be applied to the battery based on its current temperature.

The system then selects the minimum of the three generated current limits. So, for example, at a relatively low battery temperature and in a cold environment, the first current limit may be relatively higher than the third current limit as the battery is initially cool and cannot accept maximum charge and the ambient environment is relatively cold such that the battery temperature will not warm as much as it would in a relatively warmer ambient environment. Thus, the system selects the third current limit as charging at the relatively higher first current limit would exceed the third current limit. As the battery warms, however, the third current limit value may rise to a level exceeding the first value, in which case, the system will select the first current limit in place of the third current limit. In this way, the system although it can momentarily charge at a higher rate, will not select a current that will cause the battery to overheat later in the charge cycle. If in either or any situation, the maximum current from the system is less than either or both of the first and third limits, then the system will use the second current limit as the system is incapable of providing the higher first or third limit.

As noted above, when in either a hybrid heating/charging mode or charging only mode, the system is applying a complex shaped charging signal with a charging portion and a heating portion or a rest portion, either or both of which may include a positive offset such that some charge current is transferred during either the heating portion or the charging portion. The maximum charge current value may translate to various parts of the complex charging signal.

In one particular example, the maximum charging current is a mean value of the overall complex charge signal (operation 1212). The system sets a peak current of the charge portion of the signal based on the mean value (maximum charging current) as well as other parameters of the charge signal such as overall period and rest period, which may be understood as the time of the charge portion of the signal and the time of the rest portion of the signal, duty cycle, or some combination thereof. As noted above, in determining the shape of the charge portion, the system may access time parameters of the overall signal such as an overall period of the signal and a rest period. With this information, the system can determine the time of the charge portion of the signal (shaped and body).

In one possible example, the system uses the current limit (mean current) to set the peak current of the body portion of the signal while also accounting for the charge transfer that occurs during the shaped leading edge. For comparison purposes, if the system were to select an extremely high frequency harmonic for the shaped leading edge, which would appear as a conventional square wave, and the system determined a duty cycle of 50% (charge portion plus body portion is 50% and rest portion is 50%), with a current limit set at 5 A, the peak current of the charge portion would be 10 A. The system, however, for a hybrid charging and heating signal or charging signal, will generate relatively lower frequency harmonics as the shaped leading edge (not a high frequency sharp leading edge of a square wave) as such charge energy is transferred during the shaped leading edge as well as during the body portion of the charge. In the same example of a 50% duty cycle, a peak current at the upper portion of the shaped leading edge and the body portion, will be greater than 10 A if the mean current is set at 5 A as some charge is transferred during the shaped leading edge of the charge portion with the remainder transferred during the body portion of the charge. In such an example, the system considers both of the shaped leading edge and body within the 50%, and hence the peak current of the body is higher than 10 A as less energy is transferred during the shaped leading-edge portion as compared to a conventional square pulse. As such, the system, in determining the peak current, accounts for the charge transferred during the shaped portion and the body portion of the charge portion of the signal.

In nearly all instances, the peak current will be greater than the selected maximum current from operations 1204-1209. In some instances, the system may determine a peak current that is greater than possibly sourced by the hardware of the system. In such instances, the system may generate a positive charge current offset of the rest period such that the mean current may be reached over the entire period of the signal (charge portion and rest portion). In other instances, the system may adjust the overall period such that the rest period remains the same, but the charge portion increases such that the mean current may be reached over the period of one signal by lengthening the time in which the charge signal portion is delivering a charge current. In another example, the system may maintain the same overall period while shortening the rest period.

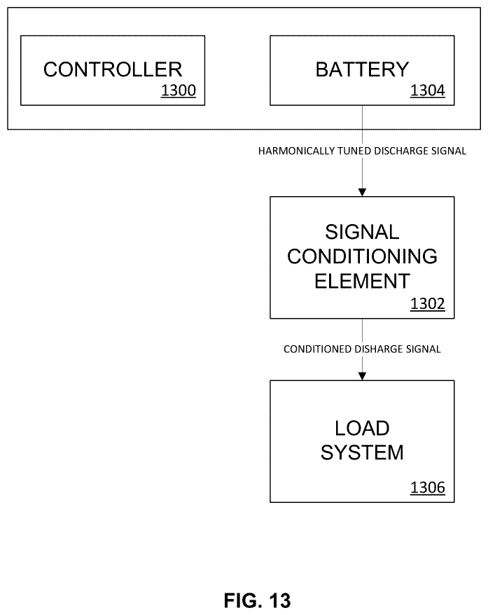

According to various aspects of the present disclosure, systems may involve a controlled discharge signal, whether part of a heating sequence or to power a load, from the battery that includes various possible harmonics (e.g., harmonic components at specified frequencies or otherwise shaped discharge signal). Referring again to FIGS. 1-3, as well as FIG. 13, the system may include the battery 104 (1304) and a controller 100 (1300) that manages the discharge signal of the battery, alone or in combination with a charge signal when in the context of heating although discharge control may be used in general operation of the system being powered by the battery to optimally discharge the battery. The controller may be some form of processing unit and may be part of a control system separate from the battery or may be integrated with the battery as in a battery management system. Regardless of the control configuration, the overall system provides a discharge signal where one or more of a leading edge of the signal, other aspects of the edge of the signal, harmonics comprising the body of the signal, and/or a trailing edge of the signal may be tuned to specific frequencies attributable to reducing and/or minimizing impedance attributes of the battery in the presence of the discharge signal during operation of the system or otherwise tailored to initially heat the battery so it may transition to charging or otherwise powering the load, in various possible examples. Regardless, a harmonic component of the discharge signal is controlled or more generally the discharge signal has unconventional non-DC attributes. The harmonic component or components may be based on an assessment of complex impedance or otherwise the attributes of the battery in the presence of discharge harmonics, to select and control harmonic components of the discharge signal that reduce or otherwise minimize the impedance attributes (e.g., complex impedance) in the presence of the discharge signal when powering a load, or generate harmonics with relatively higher impedance such that energy is primarily consumed as heat when in a heating operational mode, or other harmonic attributes are controlled for various possible reasons. Controlling the discharge in these ways has several possible advantages to the battery including optimization of heat during discharge, enhancing battery life and capacity, increasing discharge current magnitude and other advantages relative to batteries of the same type being discharged using conventional techniques.

In such a harmonically controlled discharge signal environment, however, conventional downstream systems may likely not be suitable for receiving such discharge-controlled signals from the battery. Accordingly, in one example, a discharge signal conditioning element 1302 is positioned between the battery 1304 and the load 1306 (144) or integrated within the load. The discharge signal conditioning element serves to condition the unconventional discharge signal suitable for the load or element powering the load using the energy from the battery. In one example, and referring to FIG. 1, the discharge signal conditioning element is a suitable capacitor 122 or capacitor bank, or other energy storage element, positioned to receive the discharge signal from the battery and store sufficient energy for the needs of the load. In an example, the load system 1306 may also include a DC to AC converter or other form of power conversion 146 (FIG. 1) to power a load, and the capacitor or capacitor bank is positioned between the battery and the DC to AC converter component of the load system. The harmonically controlled discharge signals are then used to charge the capacitor bank, and the capacitor bank provides the DC source required by the DC to AC converter or the load directly. The capacitor bank is sized and arranged according to the power demands of the load.

In another example, the load is configured to receive the harmonically tuned discharge signal from the battery. For a DC driven load, for example and similar to the embodiment discussed above, the load may include the capacitor 122 at the input to the load that removes the harmonic content from the discharge signal. In other examples, the discharge signal may be controlled by a buck or boost circuit that drives the load. In such an example, the buck or boost circuit may be controlled to tailor the harmonic content of the discharge signal and at the same time tune the discharge signal to the load. While the signal conditioning element and the load system are shown as separate blocks, signal conditioning may be integrated with the load system.

In some instances, a heating waveform, particularly a sinusoidal heating waveform, may be set at a frequency or include frequency attributes based on a combination of the real and imaginary components of impedance. Particularly, with regard to admittance, a heating waveform frequency may be based on a real admittance (conductance) response and an imaginary admittance (susceptance) response. The discussion is set forth in the context of admittance, and specifically conductance and susceptance, but it should be understood that it may also apply to resistance (inverse of conductance) and reactance (inverse of susceptance).

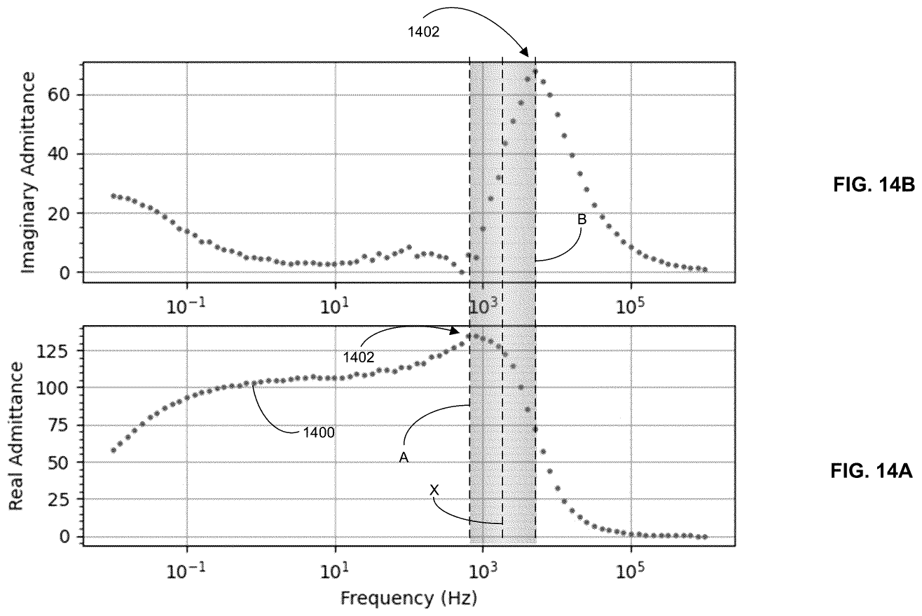

FIG. 14A is a diagram illustrating a real admittance (conductance) response 1400 of a sinusoidal signal applied to an example Lithium-Ion cell at a 50% state of charge across a spectrum of frequencies. As shown in FIG. 14A, it can be seen that at a frequency A and toward a frequency B, the conductance changes from a relatively high first conductance value at frequency A to a relatively low second conductance value at frequency B, with the conductance continuing to decrease at frequencies greater than at frequency B. In the diagram shown, frequency A is at an inflection point 1402 in the conductance response curve, where conductance is rising with increasing frequency until at frequency A, and then begins declining at frequencies above frequency A. In the example illustrated, the conductance is also at a local maximum at frequency A.

Referring to FIG. 14B, it can be seen that at about frequency A with increasing frequency to frequency B, for the same representative Lithium-Ion cell at 50% SOC, the susceptance changes from a relatively low first susceptance value to a local maximum peak susceptance value at frequency B. In the diagram shown, frequency B is at an inflection point 1402 in the susceptance response, where susceptance is rising with increasing frequency until frequency B, and then begins declining at frequencies greater than frequency B.

In various possible examples, the sinusoidal frequency of a heating signal, discussed above in various embodiments, may be established based on the conductance response, the susceptance response or a combination of both responses. As noted already, admittance is discussed recognizing it applies also to the inverse values of resistance and reactance.

In one possible example, a heating frequency may be set at some value between a frequency (e.g., frequency at A) where conductance peaks and a frequency (e.g., frequency B) where susceptance peaks. In another respect, a heating frequency may be set at some frequency value between an inflection frequency in a conductance response of a battery and an inflection frequency in a susceptance response of the battery. In the frequency zone between A and B, conductance is declining, relatively steeply, and susceptance is rising, also relatively steeply. A heating frequency may be selected from values in the frequency zone between A and B.

In a more specific example, a frequency of the heating signal is in a range around a midpoint (e.g., frequency X) between frequency A and B. Referring to FIGS. 14A and 14B, conductance peaks about 103 Hz and susceptance peaks at about 104 Hz. In this particular reference, it can be seen that the conductance peak is at a frequency less than 103 Hz and the susceptance peak is at a frequency less than 104 Hz, with the term about referring to the fact that the precise scale of the graph is not at granularity to specify the exact frequencies and the diagram instead being used to illustrate the general conductance and susceptance curve characteristics. Nonetheless, in this example, the heating frequency is chosen at a frequency X, which is about midway between the frequency A and the frequency B.

From electrochemical and electrodynamic perspectives, at frequency A electrons can move a greater total distance in the cell under charge, making it easier to cancel out the charge of the applied electric field. Consequently, and because no other materials in the cell exhibit polarizability, the cell cannot support high susceptance needed for more uniform and multi-component charge propagation and e-mobility. At frequency B, susceptance and polarizability is maximal, but electron mobility is greatly decreased, reducing heating from I²R of current collectors. At a frequency between A and B, such as at X, conductivity and I²R heating remains high, while susceptance is much higher than at frequency “A” indicating additional components and electrode area are participating in heat generation. It is known that the susceptance arises from the coiling of the electrodes in a cylindrical cell, and therefore, it can be assumed to be relatively uniform throughout the cell. Frequencies in the selected range may also be sufficiently removed from time constants associated with chemical, electrochemical, and possibly also electrokinetic mechanisms, thus avoiding nucleation and SEI growth during heating.

The frequency zone between the conductance and susceptance local maxima (inflection points) defines an area where a frequency may be selected that balances these issues and advantages. The frequency zone may also be based on either conductance or susceptance alone. For example, upon identifying a local maxima at the conductance inflection point, a frequency may be selected that is within some range of the frequency at the inflection point. In a more detailed example, the frequency may be greater than the frequency at the inflection point. The degree to which the frequency is greater may be set at some fixed offset, may be based on some difference (e.g., percentage) below the conductance value at the inflection point, or otherwise. With regard to susceptance, upon identifying a local maxima at the susceptance inflection point, a frequency may be selected that is within some range of the frequency at the inflection point. In a more detailed example, the frequency may be less than the frequency at the inflection point. The degree to which the frequency is less may be set at some fixed offset, may be based on some difference (e.g., percentage) below the susceptance value at the inflection point, or otherwise. With regard to either conductance or susceptance, the heating frequency may also be selected based on a local minima of conductance or susceptance, with a frequency less than at a local minima of conductance being chosen or a frequency greater than a local minima of susceptance being chosen. In FIGS. 14A and 14B, the local minima for susceptance is similar (slightly less) to the frequency of the conductance local maxima 1402.

The term “about” will be understood by persons of ordinary skill in the art and will vary to some extent on the context in which it is used. As used herein when referring to a value such as a frequency, temperature, current, and the like, the term “about” is meant to encompass variations of ±10%, including ±5%, ±1%, and ±0.1% from the specified value, as such variations are appropriate to perform the disclosed methods.

In various of the above examples, including the discussion of FIGS. 14A and 14B, a heating frequency may be selected based on a variety of criteria. In some examples, the frequency is based on an inflection point or a midpoint or some other criteria, and it should be recognized that there is some flexibility as to the precise number selected. So, for example, a frequency with reference to an inflection point may be at the inflection point or at about the inflection point meaning it may be within 10% of the value, or the other percentage values mentioned above. Similarly, if at a midpoint between two frequencies, that value may be within 10%, to either side, of the midpoint.

As discussed, frequencies selected between frequency A and frequency B, or more specifically within a range of midpoint frequency X, may have advantages for cell health (e.g., may be removed from the kinetically active frequencies thereby avoiding nucleation and SEI growth) and for heating (e.g., may balance between susceptance and conductance for improved heating efficiency and uniformity without degrading cell health).

Referring to FIG. 14B, it can be seen in the imaginary admittance plot (susceptance) that a frequency around 200 kHz is an approximate maximum frequency value at which a response from the battery cell is expected to be measurable. Total harmonic distortion (THD) criteria may be set to approximately 90% for frequencies under 200 KHz. Depending on hardware requirements, specific battery cells, specific system components, and desired efficiencies, a higher frequency ceiling may be selected.

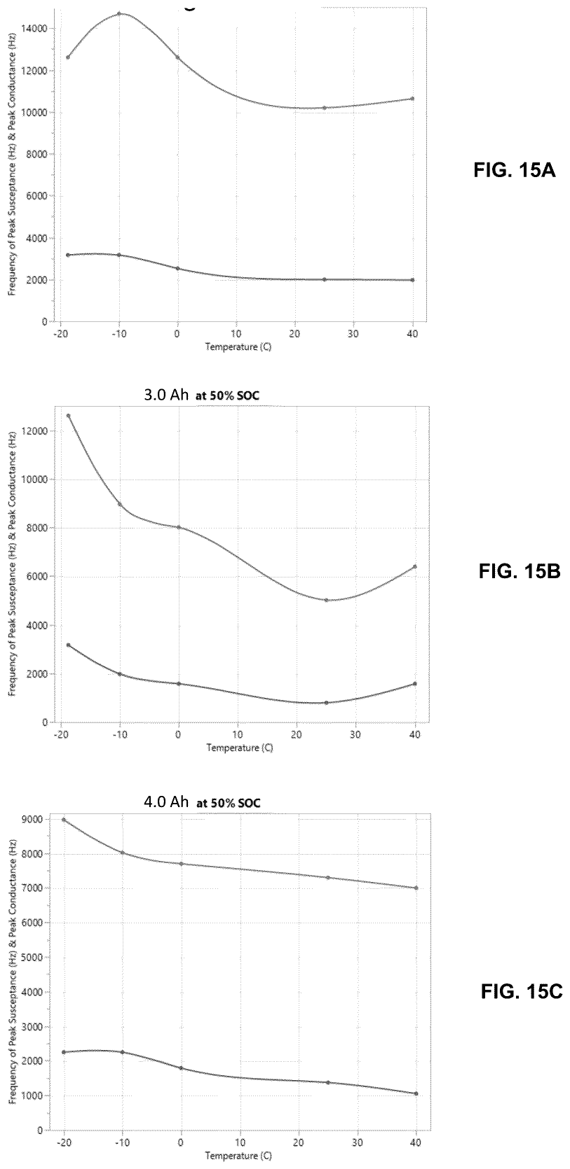

Examples of upper and lower frequency bounds as a function of temperature for different battery types are illustrated in FIGS. 15A-15C. Specifically, frequency bounds for 2.5 Ah, 3.0 Ah, and 4.0 Ah cells having 50% state of charge (SOC) are shown, respectively. Upper (e.g., at an inflection point in susceptance and peak susceptance) and lower (e.g., at an inflection point in conductance and minimum conductance) frequency bounds as a function of temperature may be based on data obtained during an initial characterization of a particular battery cell or pack. Alternatively, the bounds may be determined or adjusted dynamically in response to data obtained through intermittent probing routines performed over the life of the battery. For a characterized cell, the system may, based on cell temperature and/or SOC, select a heating frequency between the upper and lower frequency bounds. In some embodiments, a selected heating frequency may be between about 2 kHz to about 8 Khz to 1.4 MHz. In some embodiments, a selected frequency may be between 2 kHz to 1 MHz. In some embodiments, a selected frequency may be between 10 kHz and 1 MHz. It should be recognized that heating may only be required at relatively low temperatures, and the graphs depicted in FIG. 15 show data for temperatures (e.g., greater than 0° ° C. where heating is likely unnecessary or will be limited).

In some embodiments, a frequency between frequency A and frequency B of FIGS. 14A, 14B may be selected such that the heating waveform fits (e.g., completes at least one full period) within a rest portion of a charging waveform so as to minimize net coulomb exchange. An example is illustrated in FIG. 16 where a heating wave frequency is selected such that the number of heating wave periods completed within the rest period is a whole number value. For example, 10 heating wave periods are illustrated, though frequencies associated with more or fewer heating wave periods may be selected. As noted herein, during a phase when the system is both applying some level of charge signal and a heating signal, the heating signal may be applied during the rest period between active charging signals.

The time of the rest period or similarly the time between charge signal portions may be involved in selecting a frequency at which to apply the heating signal so that heating signal may complete at least one cycle between charge portions, and if more than one cycle, may complete a whole number of cycles.

FIG. 16 illustrates a sinusoidal heating wave shape; however, other shapes or combinations of shapes are also contemplated. For example, curved, linear, ramped, stepped, linear piecewise approximations of curves, and/or linear piecewise approximations of sinusoids may be used to form a heating wave. Linear piecewise approximations may include two, three, or more linear segments having different slopes within a wave period. At least one of the linear segments may have a positive slope while at least another of the linear segments may have a negative slope. In some embodiments, the selected frequency of the wave may be more impactful on cell health, heating efficiency, and/or heating uniformity than the particular shape of the wave. As such, the shape of the wave may be selected based on hardware, available processing, or other system requirements or design preferences. Similarly, a shaped leading edge of a charging waveform may have shapes that are curved, a linear normalization of a sinusoidal segment, stepped, a sequence of stepped segments, linear piecewise approximations of curves, and/or linear piecewise approximations of sinusoids.

Other heating waves includes a distribution-based wave type such as a normal distribution or other statistical distributions. In such a situation, the distribution may be centered around or related to a specific harmonic. So, the heating wave may be composed of more than one harmonic frequency distributed from a target frequency. Finally, the heating wave may be a dynamic wave. For example, the impedance curves of FIG. 14 may, in some instances, have irregular or non-symmetric shapes, and as a result, the system may generate a heating curve(s) with irregular or non-symmetric distributions of harmonics, which may be irregular in frequency and/or magnitudes. For any given system, a wave shape selection may be based in part on hardware and cost requirements. For example, a sine wave may require larger amplitudes, minimal processing, and minimal memory while providing high precision. A wave based on a fixed distribution (e.g., Gaussian) centered around an optimal frequency may allow for lower magnitudes but may have higher processing requirements and potentially lower efficiency. A wave of unconstrained shape may have the highest performance, cost, and flexibility.

In some embodiments, the heating wave may be implemented as a static wave, through use of a look-up table or the like, or implemented in a feedback or otherwise dynamic fashion. For example, in the case of a heating wave that is a sine wave, the frequency and/or magnitude of the heating wave may be fixed. In other embodiments, the frequency and/or magnitude of the heating wave may be based on a look-up table setting the frequency and/or magnitude and/or offset based on temperature of the cell or pack, based on SOC, and/or based on the number of cycles. It is possible through characterization to generate other attributes for selecting an attribute of a heating wave such as based on the charge portion of a signal when the system is both heating and charging.

A net offset (e.g., a DC voltage or current offset) for a heating wave may be based on an industry standard charge and/or discharge rate. For example, for a 30 Ah battery, the net offset for the heating wave may be selected to be around 1.5 A (C/20). Complete charge and discharge cycles at C/10-C/20 for collecting diagnostic data without impacting long term cell performance are generally accepted as standard by the industry, and might be employed as an offset to the heating wave. The net offset may also be specific to a particular battery and/or a state of charge of the battery. For example, if the state of charge of a battery is near 0% (e.g., at or less than 5% SOC, at or less than 4% SOC, at or less than 3% SOC, at or less than 2% SOC, or at or less than 1% SOC, in various possible embodiments), the offset may be biased toward charging in order to avoid over-discharge. In such a scenario where the offset is biased toward charging, the offset may be less than C/20 rate. Biased toward charging means that there is a small, e.g., at or less than C/20 rate offset, so that when applying the heating wave, the system will introduce a very modest charge current through the offset to ensure that the battery does not overdischarge. In contrast, if the state of charge of the battery is near 100% (at or greater than 95% SOC, at or greater than 96% SOC, at or greater than 97% SOC, at or greater than 98% SOC, or at or greater than 99% SOC, in various possible embodiments), the offset may be biased toward discharge, e.g., a negative offset, to avoid over-charging the battery. In this scenario, the offset may be less than C/10 rate. Here, if applying a heating wave while the battery is near 100% SOC, the heating wave is superimposed on a very modestly negative offset.

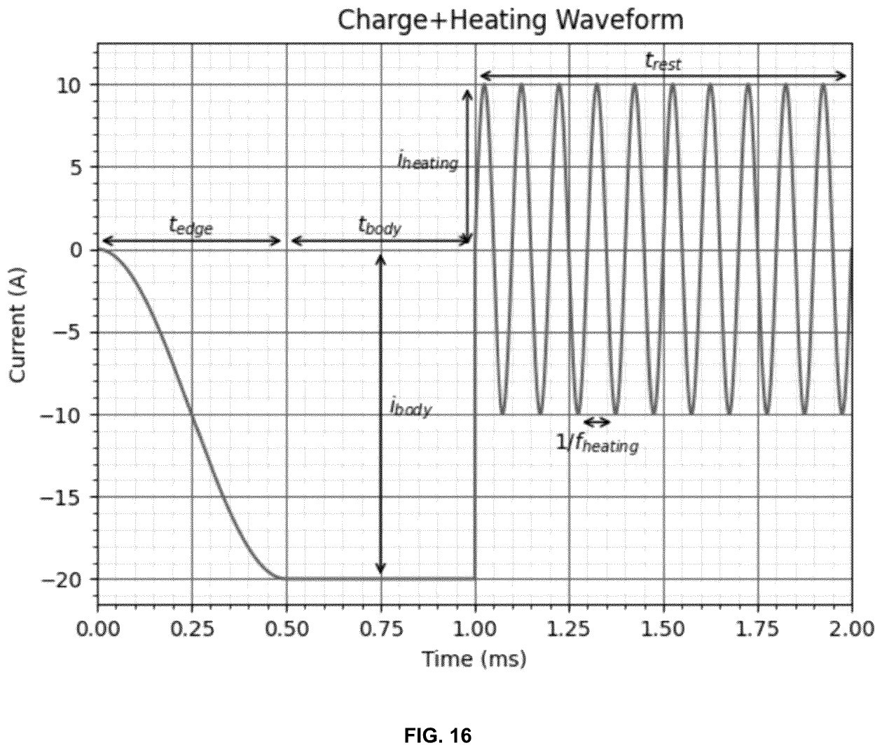

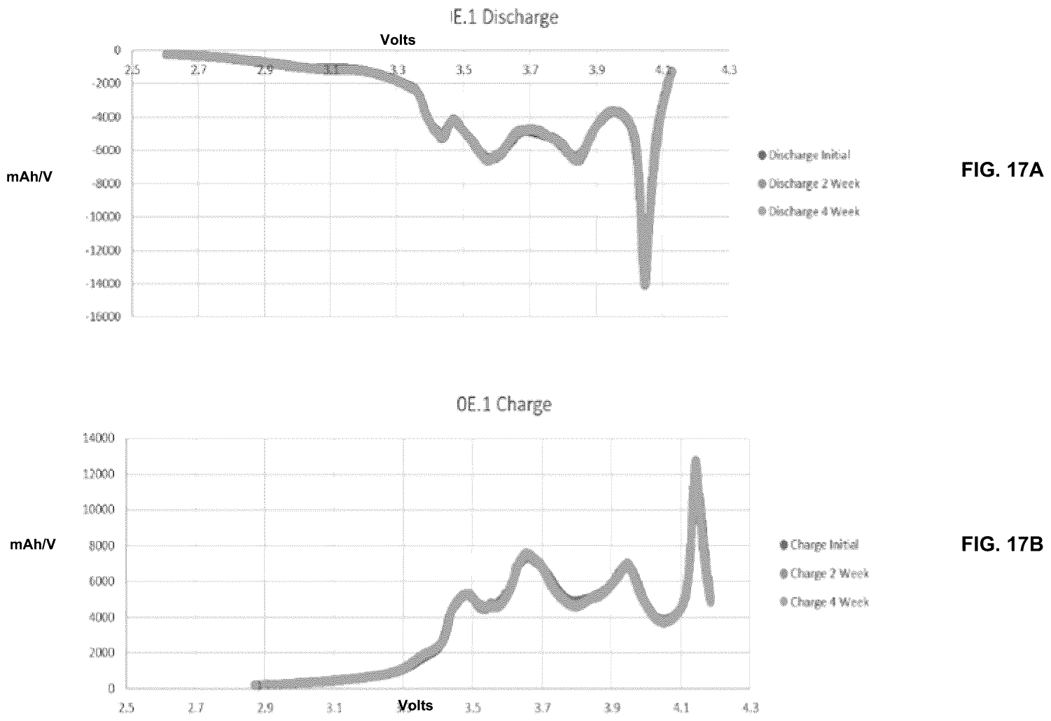

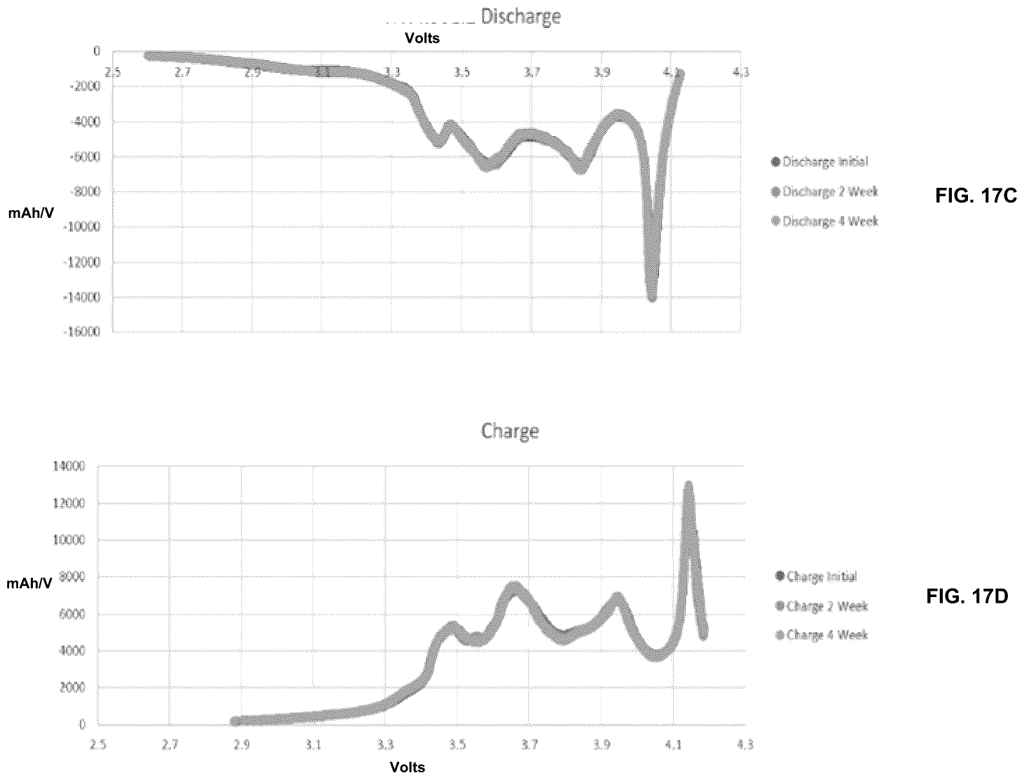

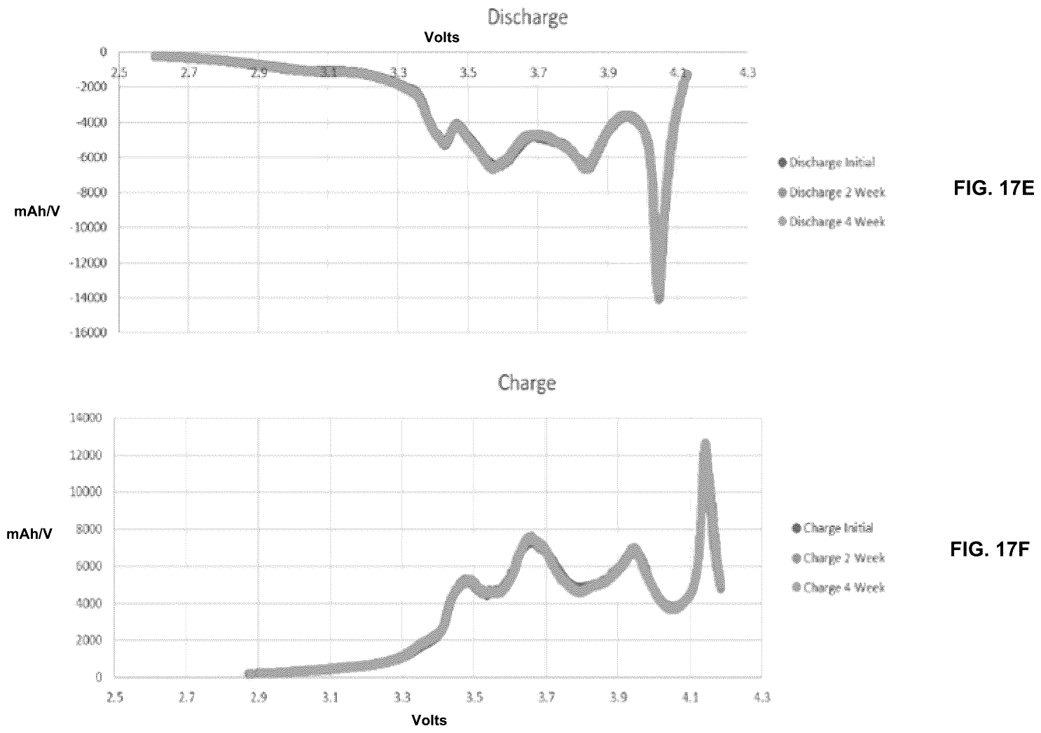

FIGS. 17A-17F show Incremental Capacity Analysis (ICA) results of before, during, and after four weeks of testing battery cells with a heating signal. In the illustrated examples, three different 5.0 Ah cells were tested at 50% SOC. The tested cells were subjected to a continuous heating wave for up to four weeks while inside a temperature-controlled chamber. The applied heating signal had a sine shape at 10 KHz frequency and 12 Amps peak-to-peak (App). ICA was performed in two-week intervals to assess component or cell aging (e.g., at the start of the test, at 2 weeks and at 4 weeks). The battery was under a continuous heating wave and the temperature chamber was actively cooling the cells or packs to keep the cells or packs at about a constant temperature. Thus, the chamber was actively countering the heat from the heating wave. Notably, the ICA shows no change in health of anode or cathode components, available battery capacity, or reversibility (discharge power potential). FIGS. 17A, 17C and 17E are ICA discharge plots for three different cells, and FIGS. 17B, 17D and 17F are ICA discharge plots for the same, respective, three cells. In each of FIGS. 17A-17B, there are actually three ICA curves from the start of the test, at 2 weeks and at 4 weeks. However, the data overlaps to such an extent that there appears to only be one curve in each graph. These results, confirm that the heating signal increases cell temperature without causing measurable changes to performance potential. As such, the heating wave described herein is safe for cell health.

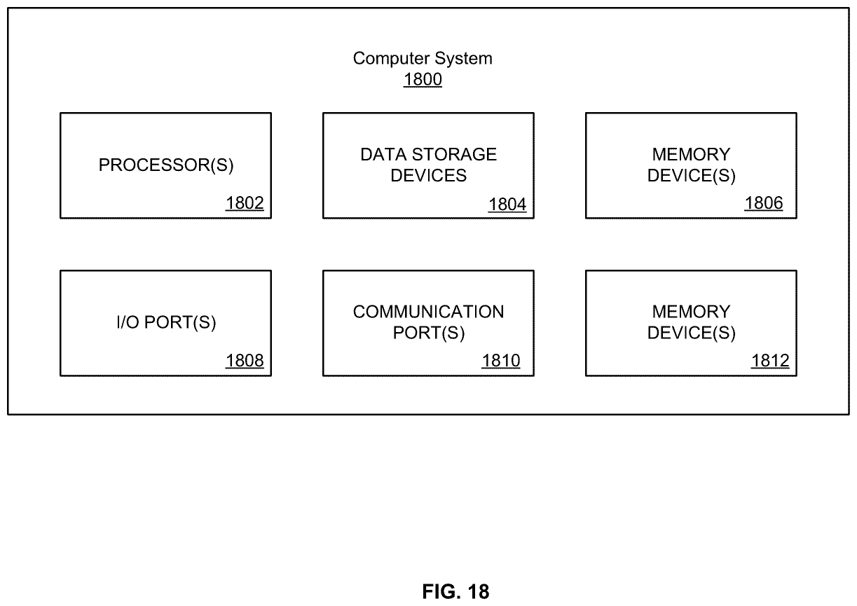

Referring to FIG. 18, a detailed description of an example computing system 1800 having one or more computing units that may implement various systems and methods discussed herein is provided. The computing system 1800 may be part of a controller, may be in operable communication with various implementation discussed herein, may run various operations related to the method discussed herein, may run offline to process various data for characterizing a battery, and may be part of overall systems discussed herein. The computing system 1800 may process various signals discussed herein and/or may provide various signals discussed herein. For example, battery measurement information may be provided to such a computing system 1800. The computing system 1800 may also be applicable to, for example, the controller, the model, the tuning/shaping circuits discussed with respect to the various figures and may be used to implement the various methods described herein. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 1800 may be a computing system that is capable of executing a computer program product to execute a computer process. Data and program files may be input to the computer system 1800, which reads the files and executes the programs therein. Some of the elements of the computer system 1800 are shown in FIG. 18, including one or more hardware processors 1802, one or more data storage devices 1804, one or more memory devices 1806, and/or one or more ports 1808-1812. Additionally, other elements that will be recognized by those skilled in the art may be included in the computing system 1800 but are not explicitly depicted in FIG. 18 or discussed further herein. Various elements of the computer system 1800 may communicate with one another by way of one or more communication buses, point-to-point communication paths, or other communication means not explicitly depicted in FIG. 18. Similarly, in various implementations, various elements disclosed in the system may or not be included in any given implementation.

The processor 1802 may include, for example, a central processing unit (CPU), a microprocessor, a microcontroller, a digital signal processor (DSP), and/or one or more internal levels of cache. There may be one or more processors 1802, such that the processor 1802 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 1804, stored on the memory device(s) 1806, and/or communicated via one or more of the ports 1808-1812, thereby transforming the computer system 1800 in FIG. 18 to a special purpose machine for implementing the operations described herein.

The one or more data storage devices 1804 may include any non-volatile data storage device capable of storing data generated or employed within the computing system 1800, such as computer executable instructions for performing a computer process, which may include instructions of both application programs and an operating system (OS) that manages the various components of the computing system 1800. The data storage devices 1804 may include, without limitation, magnetic disk drives, optical disk drives, solid state drives (SSDs), flash drives, and the like. The data storage devices 1804 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), flash drives, and the like. Examples of non-removable data storage media include internal magnetic hard disks, SSDs, and the like. The one or more memory devices 1806 may include volatile memory (e.g., dynamic random-access memory (DRAM), static random-access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 1804 and/or the memory devices 1806, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 1800 includes one or more ports, such as an input/output (I/O) port 1808, a communication port 1810, and a sub-systems port 1812, for communicating with other computing, network, or vehicle devices. It will be appreciated that the ports 1808-1812 may be combined or separate and that more or fewer ports may be included in the computer system 1800. The I/O port 1808 may be connected to an I/O device, or other device, by which information is input to or output from the computing system 1800. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 1800 via the I/O port 1808. In some examples, such inputs may be distinct from the various system and method discussed with regard to the preceding figures. Similarly, the output devices may convert electrical signals received from computing system 1800 via the I/O port 1808 into signals that may be sensed or used by the various methods and system discussed herein. The input device may be an alphanumeric input device, including alphanumeric and other keys for communicating information and/or command selections to the processor 1802 via the I/O port 1808.

The environment transducer devices convert one form of energy or signal into another for input into or output from the computing system 1800 via the I/O port 1808. For example, an electrical signal generated within the computing system 1800 may be converted to another type of signal, and/or vice-versa. In one implementation, the environment transducer devices sense characteristics or aspects of an environment local to or remote from the computing device 1800, such as battery voltage, open circuit battery voltage, charge current, battery temperature, light, sound, temperature, pressure, magnetic field, electric field, chemical properties, and/or the like.

In one implementation, a communication port 1810 may be connected to a network by way of which the computer system 1800 may receive network data useful in executing the methods and systems set out herein as well as transmitting information and network configuration changes determined thereby. For example, charging protocols may be updated, battery measurement or calculation data shared with external system, and the like. The communication port 1810 connects the computer system 1800 to one or more communication interface devices configured to transmit and/or receive information between the computing system 1800 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 1810 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 1800 may include a sub-systems port 1812 for communicating with one or more systems related to a device being charged according to the methods and system described herein to control an operation of the same and/or exchange information between the computer system 1800 and one or more sub-systems of the device. Examples of such sub-systems of a vehicle, include, without limitation, motor controllers and systems, battery control systems, and others.

The system set forth in FIG. 18 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various operations, which are described in this specification. The operations may be performed by hardware components or may be embodied in machine-executable instructions, which may be used to cause a general-purpose or special-purpose processor programmed with the instructions to perform the operations. Alternatively, the operations may be performed by a combination of hardware, software and/or firmware.

Various modifications and additions can be made to the exemplary embodiments discussed without departing from the scope of the present disclosure. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations, examples and embodiments (terms used synonymously herein) are discussed, it should be understood that this is done for illustration purposes only. A person skilled in the relevant art will recognize that other components and configurations may be used without parting from the spirit and scope of the disclosure. Thus, the description and drawings are illustrative and are not to be construed as limiting. Numerous specific details are described to provide a thorough understanding of the disclosure. However, in certain instances, well-known or conventional details are not described in order to avoid obscuring the description.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance” or similar phrases, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given above. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Various features and advantages of the disclosure are set forth in the description above, and in part will be obvious from the description, or can be learned by practice of the herein disclosed principles. The features and advantages of the disclosure can be realized and obtained by means of the instruments and combinations particularly pointed out in the appended claims.

What is claimed:

1. A method of heating a battery comprising:
generating a repeating signal to apply to a battery, the repeating signal having first portion and a second portion over a period, the first portion defining a leading edge rising to a body portion terminating in a falling edge, the second portion comprising an alternating current following the falling edge of the first portion, and
wherein a frequency of the alternating current is selected to be between 2 kHz and 1 MHz.

2. The method of claim 1, wherein the alternating current is a sinusoidal shape.

3. The method of claim 2, wherein the alternating current comprises an approximation of the sinusoidal shape.

4. The method of claim 3, wherein the approximation is a linear piecewise approximation of the sinusoidal shape.

5. The method of claim 4, wherein each period of the linear piecewise approximation comprises at least three linear segments having different slopes.

6. The method of claim 1, wherein the alternating current comprises a first linear ramp with a positive slope and a second linear ramp with a negative slope.

7. The method of claim 1, further comprising selecting an offset for the alternating current based on a state of charge of the battery.

8. The method of claim 7, wherein the offset is selected to charge the battery when the battery state of charge is about zero.

9. The method of claim 8, wherein the offset is a current offset at or less than C/20.

10. The method of claim 8, wherein the offset is selected to discharge the battery when the battery state of charge is about full.

11. The method of claim 10, wherein the offset is at or less than C/10.

12. The method of claim 1, wherein the frequency is selected such that at least one full period of the alternating current fits between the falling edge of the first portion of a first repeating signal and the leading edge of the first portion of a second repeating signal.

13. The method of claim 1, wherein the frequency of the alternating current is selected such that a number of alternating current periods completed between sequential first portions of the signal is a whole number.

14. The method of claim 1, wherein the frequency of the alternating current is selected to target a net zero coulomb exchange.

15. The method of claim 1, further comprising probing the battery to dynamically determine an upper frequency bound and a lower frequency bound with the lower frequency bound at an inflection point in a conductance response and the upper frequency bound at an inflection point in a susceptance response.

16. The method of claim 15, wherein the frequency is selected between the upper frequency bound and the lower frequency bound.

17. A method of heating a battery comprising:
generating a repeating signal to apply to a battery, the repeating signal having first portion and a second portion over a period, the first portion defining a charging portion terminating in a falling edge, the second portion comprising an alternating current following the falling edge of the first portion, and
wherein a frequency of the alternating current is based on at least one of a conductance response or a susceptance response.

18. The method of claim 17, wherein the frequency is between an upper frequency bound and a lower frequency bound with the lower frequency bound at an inflection point in the conductance response and the upper frequency bound at an inflection point in the susceptance response.

19. The method of claim 18, further comprising probing the battery to dynamically determine the upper frequency bound and the lower frequency bound with the lower frequency bound at an inflection point in a conductance response and the upper frequency bound at an inflection point in a susceptance response.

20. The method of claim 17 wherein the frequency is further based on a temperature of the battery.
